(19) United States
(12) Patent Application Publication
(10) Pub. No.: US 2026/0033031 A1
(43) Pub. Date: Jan. 29, 2026

(54) IMAGE SENSOR

(71) Applicant: Samsung Electronics Co., Ltd., Suwon-si (KR)

(72) Inventors: Sang-Hoon Kim, Suwon-si (KR); Sewoong Yang, Suwon-si (KR)

(21) Appl. No.: 19/038,306

(22) Filed: Jan. 27, 2025

(30) Foreign Application Priority Data
Jul. 26, 2024 (KR) 10-2024-0099558

(51) Int. Cl. H10F 39/00; H10F 39/18

(52) U.S. Cl. CPC H10F 39/807; H10F 39/182; H10F 39/806; H10F 39/8063; H10F 39/8067

(57) ABSTRACT

An image sensor includes a substrate, a plurality of photodiodes in the substrate, an element isolation pattern, and a photodiode isolation pattern. The photodiode isolation pattern includes a conductive isolation pattern that extends into at least a portion of the substrate and an insulating isolation pattern that extends around the conductive isolation pattern. A width in a first direction of a first surface of the insulating isolation pattern adjacent to the first surface of the substrate is greater than a width in the first direction of a second surface of the insulating isolation pattern adjacent to the second surface of the substrate. A slope relative to the second surface of the substrate of a side of the conductive isolation pattern is greater than a slope relative to the second surface of the substrate of a side of the insulating isolation pattern.

### CROSS-REFERENCE TO RELATED APPLICATION

This application claims priority to and the benefit of Korean Patent Application No. 10-2024-0099558 filed in the Korean Intellectual Property Office on Jul. 26, 2024, the entire contents of which are incorporated herein by reference.

### TECHNICAL FIELD

The present disclosure relates to an image sensor.

### BACKGROUND

A CMOS image sensor is a solid-state imaging device that uses a complementary metal-oxide semiconductor (CMOS).

The pixel array that makes up the CMOS image sensor includes a photodiode for each pixel.

Recently, due to an increasing demand for high-resolution images through downsizing, noise may occur due to an interference between elements where incident light is not properly sensed or an integration is increased.

Accordingly, various studies are being conducted on the shape of photodiode isolation patterns to prevent or inhibit crosstalk between adjacent pixels and minimize a light loss incident on the pixels.

### SUMMARY

Embodiments disclosed herein include an image sensor with improved optical characteristics.

An image sensor according to some embodiments includes a substrate including a first surface and a second surface facing the first surface, a plurality of photodiodes in the substrate, an element isolation pattern adjacent to the first surface of the substrate, and a photodiode isolation pattern that extends into the element isolation pattern and is between the plurality of photodiodes. The photodiode isolation pattern includes a conductive isolation pattern that extends into at least a portion of the substrate and an insulating isolation pattern that extends around the conductive isolation pattern. A width in a first direction of a first surface of the insulating isolation pattern adjacent to the first surface of the substrate is greater than a width in the first direction of a second surface of the insulating isolation pattern adjacent to the second surface of the substrate. A slope relative to the second surface of the substrate of a side of the conductive isolation pattern is greater than a slope relative to the second surface of the substrate of a side of the insulating isolation pattern.

An image sensor according to some embodiments includes a substrate including a first surface and a second surface facing the first surface, a plurality of photodiodes in the substrate, an element isolation pattern adjacent to the first surface of the substrate, a photodiode isolation pattern that extends into the element isolation pattern and is between the plurality of photodiodes, and a scattering pattern adjacent to the second surface of the substrate. The photodiode isolation pattern includes an insulating isolation pattern that extends into at least a portion of the substrate and has a width in a first direction that decreases from the first surface of the substrate to the second surface of the substrate. A ratio of a width of a first surface of the photodiode isolation pattern adjacent to the first surface of the substrate and a width of a second surface of the photodiode isolation pattern adjacent to the second surface of the substrate is about 1.2:1 to 2:1.

An image sensor according to some embodiments includes a substrate including a first surface and a second surface facing the first surface, a plurality of photodiodes in the substrate, an element isolation pattern adjacent to the first surface of the substrate, a photodiode isolation pattern that extends into the element isolation pattern and is between the plurality of photodiodes, a scattering pattern adjacent to the second surface of the substrate, a plurality of grid patterns on the second surface of the substrate, a micro lens layer including a flat portion that is between and on ones of the plurality of grid patterns and a micro lens on the flat portion, and an air gap that is on the first surface of the substrate and at least partially overlaps the photodiode isolation pattern in a first direction that is perpendicular to the first surface of the substrate. The photodiode isolation pattern includes a conductive isolation pattern that extends into at least a portion of the substrate, a buried insulating pattern on the conductive isolation pattern, and an insulating isolation pattern that extends around the conductive isolation pattern and the buried insulating pattern and has a width in a second direction that decreases from the first surface of the substrate to the second surface of the substrate, where the second direction is parallel to the first surface of the substrate. A ratio of a width of a first surface of the photodiode isolation pattern adjacent to the first surface of the substrate and a width of a second surface of the photodiode isolation pattern adjacent to the second surface of the substrate is about 1.2:1 to 2:1. A ratio of a width of a first surface of the insulating isolation pattern adjacent to the first surface of the substrate and a width of a second surface of the insulating isolation pattern adjacent to the second surface of the substrate is about 1.5:1 to 3:1. A slope relative to the second surface of the substrate of a side of the conductive isolation pattern is greater than a slope relative to the second surface of the substrate of the side of the insulating isolation pattern.

According to embodiments, the width of the insulating isolation pattern included in the photodiode isolation pattern positioned between the plurality of photodiodes decreases toward the light-receiving surface of the substrate, thereby preventing or inhibiting a pixel size reduction and a crosstalk phenomenon at the same time.

### BRIEF DESCRIPTION OF THE DRAWINGS

FIG. 1 is a top plan view of an image sensor according to some embodiments of the present disclosure.

FIG. 2 is a top plan view showing a portion of an image sensor according to some embodiments of the present disclosure.

FIG. 3 is a cross-sectional view taken along a line I-I′ of FIG. 2.

FIG. 4 is an enlarged view of a region P1 of FIG. 3.

FIG. 5 to FIG. 11 are cross-sectional views showing a cross-section of an image sensor according to some embodiments of the present disclosure.

FIG. 12 is a cross-sectional view showing a cross-section of an image sensor according to some embodiments of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present invention.

Parts unrelated to the description of the embodiments are not shown to make the description clear, and like reference numerals designate like element throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

Also, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section by vertically cutting a target portion from the side. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

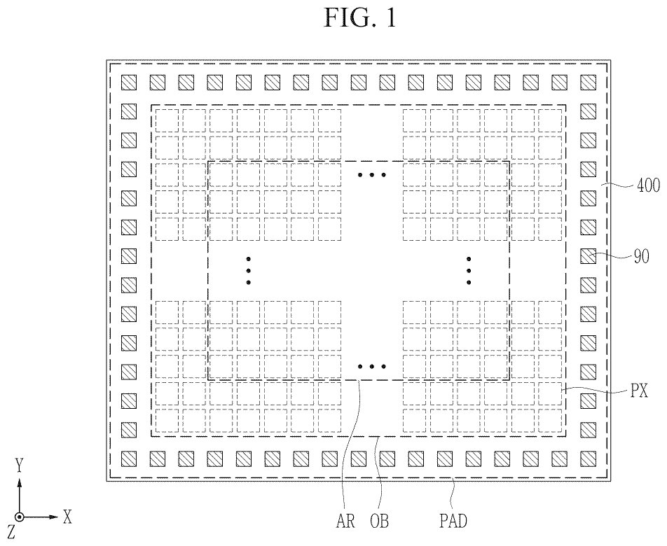

Hereinafter, an image sensor according to some embodiments is described with reference to FIG. 1 to FIG. 4.

FIG. 1 is a top plan view of an image sensor according to an embodiment. Referring to FIG. 1, a substrate 400 may include a pixel array region AR, an optical black region OB, and a pad region PAD on a plane. The pixel array region AR may be positioned approximately at the central portion of the substrate 400 on a plane.

The pixel array region AR may include a plurality of pixels PX. The pixel PX may output a photoelectric signal from an incident light. The pixels PX may be arranged along rows parallel to a first direction X and columns parallel to a second direction Y.

The pad region PAD may be positioned at the edge of the substrate 400 and surround or extend around the pixel array region AR.

The optical black region OB may be positioned between the pixel array region AR and the pad region PAD of the substrate 400.

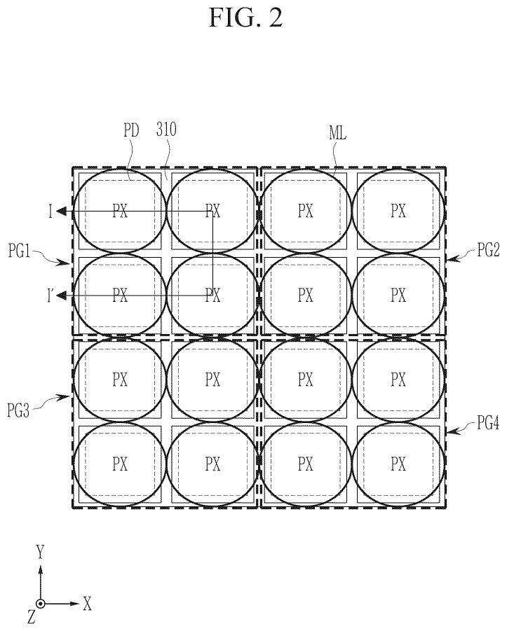

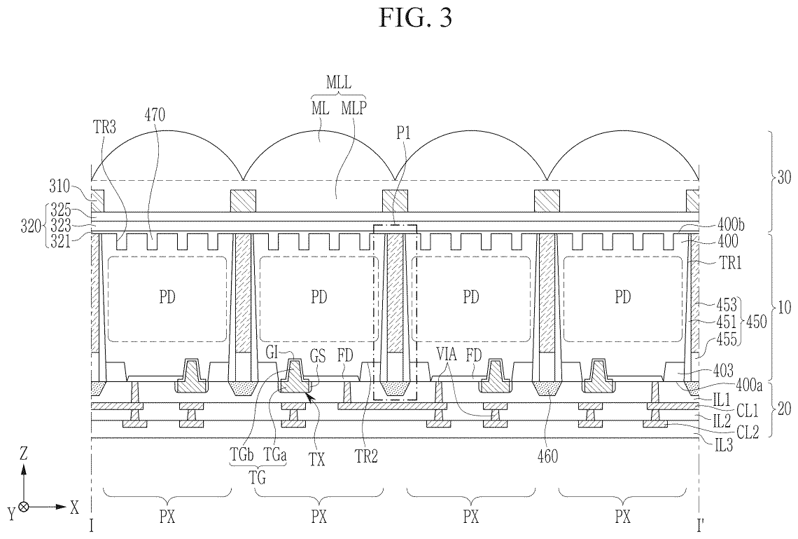

FIG. 2 is a top plan view showing a portion of an image sensor according to an embodiment. FIG. 3 is a cross-sectional view taken along a line I-I′ of FIG. 2.

Referring to FIG. 2 and FIG. 3, an image sensor according to some embodiments may include a photoelectric conversion layer 10, a wire region 20, and a light transmitting layer 30.

The photoelectric conversion layer 10 may be positioned between the wire region 20 and the light transmitting layer 30. That is, the wire region 20, the photoelectric conversion layer 10, and the light transmitting layer 30 may be sequentially positioned along a third direction Z, which is a vertical direction.

The photoelectric conversion layer 10 may include a substrate 400 including a first surface 400a and a second surface 400b facing each other, a plurality of photodiodes PD positioned in the substrate 400, an element isolation pattern 403 adjacent to the first surface 400a of the substrate 400, a photodiode isolation pattern 450 between the plurality of photodiodes PD, and a scattering pattern 470 positioned adjacent to the second surface 400b of the substrate 400.

Light incident from the outside may be converted into an electrical signal in each photodiode PD.

The substrate 400 may include a first surface 400a and a second surface 400b facing each other in the third direction Z, which is the vertical direction. The second surface 400b of the substrate 400 may be a light-receiving surface onto which light is incident.

The wire region 20 may be positioned on the first surface 400a of the substrate 400, and light transmitting layer 30 may be positioned on the second surface 400b of the first substrate 400. That is, the substrate 400 may be positioned between the wire region 20 and the light transmitting layer 30.

The substrate 400 may be a semiconductor substrate or a silicon on insulator (SOI) substrate. The semiconductor substrate may include, for example, a silicon substrate, a germanium substrate or a silicon-germanium substrate. The substrate 400 may include impurities of a first conductivity type.

The substrate 400 may include a plurality of pixels PX defined by a photodiode isolation pattern 450. The plurality of pixels PX may output a photoelectric signal from an incident light incident from the outside. For example, the incident light from the outside onto photodiodes PD may be infrared light with a long wavelength. That is, the image sensor according to some embodiments may detect light reflected from an object by using infrared light and output an optical depth information about the object. For example, color filters with colors such as red, green, and blue may be positioned between the photodiode PD and the micro lens ML to absorb infrared light with a long wavelength. As another example, a transmitting layer that transmits all light may be positioned between the photodiode PD and the micro lens ML instead of the color filter, and the transmitting layer may include the same material as the micro lens ML.

As shown in FIG. 2, the plurality of pixels PX may be arranged in a matrix shape along rows parallel to the first direction X and columns parallel to the second direction Y on a plane.

Specifically, a plurality of pixels PX may form first to fourth pixel groups PG1, PG2, PG3, and PG4. That is, the first to fourth pixel groups PG1, PG2, PG3, and PG4 may include the N×M pixels PX in an N×M array. N and M may each independently be integers greater than 1. For example, the first to fourth pixel groups PG1, PG2, PG3, and PG4 may each include four adjacent pixels PX arranged in two rows and two columns. However, the number and arrangement of the pixels PX included in one pixel group is not limited to this and may be changed in various ways. For example, the first to fourth pixel groups PG1, PG2, PG3, and PG4 may each include nine adjacent pixels PX arranged in three rows and three columns. As another example, the first to fourth pixel groups PG1, PG2, PG3, and PG4 may each include 16 adjacent pixels PX arranged in four rows and four columns.

The photodiode isolation pattern 450 may be positioned between the plurality of pixels PX. As shown in FIG. 3, the photodiode isolation pattern 450 may be positioned within a first trench TR1 penetrating or extending into at least a portion of the substrate 400 on the cross-section.

The photodiode isolation pattern 450 may be a deep trench isolation (DTI) layer. The photodiode isolation pattern 450 may penetrate or extend into at least a portion of the substrate 400. For example, the photodiode isolation pattern 450 may penetrate through or extend into the entire substrate 400, and one surface of the photodiode isolation pattern 450 may be in contact with the first surface 400a of the substrate 400, while the other surface may be in contact with the second surface 400b of the substrate 400. That is, one end of the photodiode isolation pattern 450 may be in contact with the first surface 400a of the substrate 400, and the other end may be in contact with the second surface 400b of the substrate 400.

Although not shown, in some embodiments, the photodiode isolation pattern 450 may be positioned within a trench formed by recessing a portion of the substrate 400. That is, one surface of the photodiode isolation pattern 450 may be positioned in contact with the first surface 400a of the substrate 400, and the other surface may be positioned away from the second surface 400b of the substrate 400. In other words, the length of the photodiode isolation pattern 450 along the third direction Z may be smaller than the length or thickness of the substrate 400 along the third direction Z.

In this way, when the other surface of the photodiode isolation pattern 450 is positioned apart from the second surface 400b of the substrate 400, the other surface of the photodiode isolation pattern 450 may have a rounded shape.

Additionally, although not shown, in some embodiments, the photodiode isolation pattern 450 may further include a channel stop region (not shown). That is, the photodiode isolation pattern 450 may further include the channel stop region positioned between the second surface 400b of the substrate 400 and the other surface of the photodiode isolation pattern 450.

The channel stop region may be doped with a conductivity type different from the photodiode PD. For example, the photodiode PD may be doped with an N-type impurity, and the channel stop region may be doped with a P-type impurity.

The photodiode isolation pattern 450 may include an insulating isolation pattern 451, a conductive isolation pattern 453, and a buried insulating pattern 455.

The insulating isolation pattern 451 may extend along the inner surface of the first trench TR1. The insulating isolation pattern 451 may penetrate or extend into at least a portion of the substrate 400. The insulating isolation pattern 451 may include a material having a refractive index lower than substrate 400. For example, the insulating isolation pattern 451 may include a silicon-based insulating material (e.g., silicon nitride, silicon oxide or silicon oxide nitride) or a high-dielectric material (e.g., hafnium oxide or aluminum oxide). However, the material included in the insulating isolation pattern 451 is not limited thereto and may be varied.

Since the photodiode isolation pattern 450 includes the insulating isolation pattern 451, a crosstalk phenomenon between the adjacent pixels PX can be prevented or reduced.

The conductive isolation pattern 453 may be positioned on the insulating isolation pattern 451. The conductive isolation pattern 453 may penetrate or extend into at least a portion of the substrate 400. Both sides of the conductive isolation pattern 453 may be surrounded by the insulating isolation pattern 451 (e.g., the insulating isolation pattern 451 extends around the conductive isolation pattern 453). The insulating isolation pattern 451 may be positioned between the conductive isolation pattern 453 and the substrate 400. The conductive isolation pattern 453 may be separated from the substrate 400 by the insulating isolation pattern 451. Accordingly, when the image sensor 100 is operating, the conductive isolation pattern 453 may be electrically isolated from the substrate 400.

The conductive isolation pattern 453 may include a crystalline semiconductor material such as polycrystalline silicon, the conductive isolation pattern 453 further includes a dopant, and the dopant may include an impurity of a first conductivity type or an impurity of a second conductivity type. As another example, the conductive isolation pattern 453 may include a doped polycrystalline silicon. As another example, the conductive isolation pattern 453 may include an undoped crystalline semiconductor material. As another example, the conductive isolation pattern 453 may include an undoped polycrystalline silicon. The term “undoped” may imply that no intentional doping process has been performed. The dopant may include an N-type dopant and a P-type dopant. However, the material included in the conductive isolation pattern 453 is not limited thereto and may be varied.

The buried insulating pattern 455 may be positioned over the conductive isolation pattern 453. The insulating isolation pattern 451 may surround or extend around the conductive isolation pattern 453 and the buried insulating pattern 455. The conductive isolation pattern 453 and the buried insulating pattern 455 may be positioned to overlap each other in the vertical direction, and the buried insulating pattern 455 may be placed adjacent to the first surface 400a of the substrate 400. That is, the buried insulating pattern 455 may be positioned between the conductive isolation pattern 453 and the first surface 400a of the substrate 400.

The buried insulating pattern 455 may include a non-conductive material. The buried insulating pattern 455 may include a silicon-based insulating material (e.g., silicon nitride, silicon oxide or silicon oxide nitride) or a high-dielectric material (e.g., hafnium oxide or aluminum oxide). However, the material included in the buried insulating pattern 455 is not limited thereto and may be changed in various ways.

Accordingly, the photodiode isolation pattern 450 may prevent or inhibit photo charges generated by incident light incident on the pixel PX from being incident on other adjacent pixels PX due to a random drift.

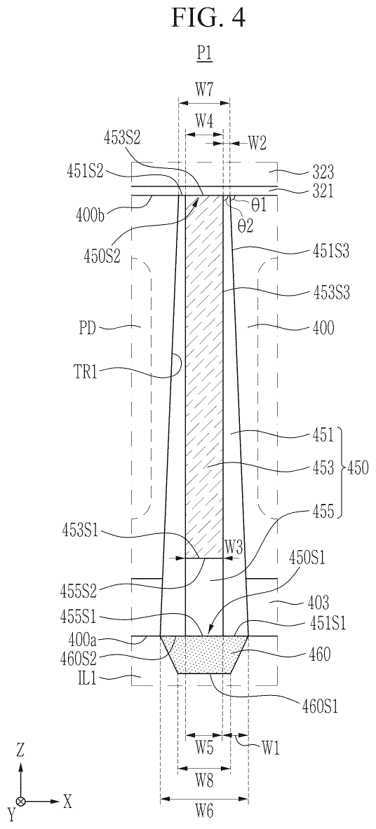

The detailed description of the photodiode isolation pattern 450 is described below along with FIG. 4.

The plurality of photodiodes PD may be positioned within the substrate 400 and receive light. The plurality of photodiodes PD may be positioned to correspond to each of the plurality of pixels PX. That is, the plurality of photodiodes PD may have substantially the same arrangement in the plane as the plurality of pixels PX.

Light incident from outside may be converted into electrical signals by the photodiodes PD. The photodiodes PD may generate and accumulate photo charges proportional to the intensity of the incident light.

The photodiodes PD may be regions doped with the second conductivity type impurity within the substrate 400. The impurity of the second conductivity type may have a conductivity type opposite to the impurity of the first conductivity type. The impurity of the second conductivity type may include N-type impurities such as phosphorus, arsenic, bismuth, and/or antimony.

Each of the photodiodes PD may include a first region adjacent to the first surface 400a of the substrate 400 and a second region adjacent to the second surface 400b. The impurity concentrations in the first region and the second region of the photodiodes PD may be different.

Accordingly, the photodiodes PD may have a potential slope between the first surface 400a and the second surface 400b of the substrate 400. However, in some embodiments, the photodiodes PD may not have a potential slope between the first surface 400a and the second surface 400b of the first substrate 400.

The element isolation pattern 403 may be positioned within the substrate 400. The element isolation pattern 403 may be positioned adjacent to the first surface 400a of the substrate 400. For example, the element isolation pattern 403 may be positioned within the second trench TR2 on the cross-section. The second trench TR2 may be recessed from the first surface 400a of the substrate 400 toward the second surface 400b. The element isolation pattern 403 may be a shallow trench isolation (STI) film.

The element isolation pattern 403 may be penetrated by the photodiode isolation pattern 450 (e.g., the photodiode isolation pattern 450 may extend into the element isolation pattern 403). That is, the element isolation pattern 403 may surround or extend around a part of the side of the photodiode isolation pattern 450. In other words, the element isolation pattern 403 may surround or extend around the side of the photodiode isolation pattern 450 positioned adjacent to the first surface 400a of the substrate 400.

The element isolation pattern 403 may define an active pattern (not shown). The width of element isolation pattern 403 along the first direction X may decrease from the first surface 400a of the substrate 400 to the second surface 400b. The element isolation pattern 403 may be positioned apart from the photodiodes PD.

In FIG. 3 and FIG. 4, one surface of the element isolation pattern 403 positioned adjacent to the first surface 400a of the substrate 400 and the first surface 400a of the substrate 400 are shown as being flat, but one surface of the element isolation pattern 403 and the first surface 400a of the substrate 400 may have a curve. That is, one surface of the element isolation pattern 403 and the first surface 400a of the substrate 400 may be positioned at different levels.

Also, in FIG. 3 and FIG. 4, although a boundary between the insulating isolation pattern 451 and the buried insulating pattern 455 included in the photodiode isolation pattern 450, and the element isolation pattern 403 is shown, in some embodiments, there may be no boundary between the insulating isolation pattern 451, the buried insulating pattern 455, and the element isolation pattern 403 when they are formed of the same material (e.g., silicon oxide). In this case, the insulating isolation pattern 451 of the photodiode isolation pattern 450, the buried insulating pattern 455, and the element isolation pattern 403 may be formed integrally.

In an embodiment, the photoelectric conversion layer 10 may further include a transmission transistor TX including a transmission gate TG and a plurality of floating diffusion regions FD.

The transmission transistor TX including the transmission gate TG may be positioned on the first surface 400a of the substrate 400. In an embodiment, the transmission gate TG may be of a vertical type. A part of the transmission gate TG may be positioned within the substrate 400, and the remaining part may be protruded onto or extend toward the first surface 400a of the substrate 400.

For example, the transmission gate TG may include a first portion TGa positioned on the first surface 400a of the substrate 400 and a second portion TGb positioned within the substrate 400 and extending from the first surface 400a of the substrate 400 toward the second surface 400b. However, the shape of the transmission gate TG is not limited to this and may be changed in various ways. For example, the transmission gate TG may be a planar type in which the second portion TGb is omitted and only the first portion TGa is included.

A gate spacer GS may be positioned on both sides of the first portion TGa of the transmission gate TG. The gate spacer GS may include, for example, silicon nitride, silicon carbonization nitride or silicon oxidation nitride. However, this is an example, and the material included in the gate spacer GS may vary.

A gate dielectric layer GI may be positioned between the transmission gate TG and the substrate 400. For example, the gate dielectric layer GI may be positioned between the second portion TGb of the transmission gate TG and the substrate 400.

In an embodiment, the photoelectric conversion layer 10 may further include a plurality of floating diffusion regions FD positioned adjacent to the first surface 400a of the substrate 400.

The plurality of floating diffusion regions FD may be positioned within the substrate 400. The charges in the photodiodes PD may be transferred to the floating diffusion region FD. The floating diffusion region FD may maintain the charge transferred from the photodiode PD. The floating diffusion region FD may be doped with the impurity of the second conductivity type. For example, the impurity of the second conductivity type may be the N-type impurity.

The floating diffusion region FD may be buried in the substrate 400 and extend from the first surface 400a of the substrate 400 toward the second surface 400b. The floating diffusion region FD may be positioned between the transmission gate TG and the element isolation pattern 403. The floating diffusion region FD may be connected to one terminal of the transmission transistor TX.

The photoelectric conversion layer 10 according to some embodiments may include a plurality of scattering patterns 470. The plurality of scattering patterns 470 may be positioned adjacent to the second surface 400b of the substrate 400 and arranged to be spaced by a predetermined distance between the photodiode isolation patterns 450. The plurality of scattering patterns 470 may be positioned apart from the photodiode PD.

In FIG. 3, the plurality of scattering patterns 470 are illustrated as being arranged at a regular interval, but the arrangement of the interval of the plurality of scattering patterns 470 are not limited thereto and may be changed in various ways. For example, the separation distance between one of the plurality of scattering patterns 470 and another one of the plurality of scattering patterns 470 may be different from the separation distance between another one of the plurality of scattering patterns 470 and another one of the plurality of scattering patterns 470.

The scattering pattern 470 may be positioned within the third trench TR3 recessed from the second surface 400b of the substrate 400 toward the first surface 400a on the cross-section.

The scattering pattern 470 may include the same material as a part of the insulating structure 320 described below. For example, in a process of forming a first fixing charge layer 321 included in the insulating structure 320, the scattering pattern 470 may be formed as a portion of the first fixing charge layer 321 fills the third trench TR3.

The scattering pattern 470 and the first fixing charge layer 321 of the insulating structure 320 may be formed simultaneously by substantially the same process and may be formed integrally with each other. However, this is an example, and the scattering pattern 470 may be formed by at least partially filling a material different from the first fixing charge layer 321 in the third trench TR3.

In this way, when the first fixing charge layer 321 and the scattering pattern 470 include different materials, there may be a boundary between the first fixing charge layer 321 and the scattering pattern 470, unlike as illustrated in FIG. 3.

In FIG. 3, it is shown that the scattering pattern 470 has a quadrangle shape in the cross-sectional view (e.g., a cross-sectional shape) and the width of the scattering pattern 470 along the first direction X is constant, but the shape of the cross-section of the scattering pattern 470 is not limited thereto and may be changed in various ways. For example, the shape of the scattering pattern 470 in the cross-sectional view may have a shape in which the width in the first direction X decreases or increases as it goes from the second surface 400b of the substrate 400 to the first surface 400a.

In addition, in FIG. 3, the scattering pattern 470 positioned within the third trench TR3 is illustrated as being composed of one layer, but is not limited thereto, and the scattering pattern 470 may be composed of a plurality of layers sequentially stacked within the third trench TR3. For example, the scattering pattern 470 positioned within the third trench TR3 is composed of the plurality of layers, at least some of which may include a material different from the first fixing charge layer 321.

The plurality of scattering patterns 470 may increase an optical path of incident light by scattering the incident light incident on the photodiode PD. That is, the incident light from the outside may be scattered to multiple points rather than one point by the scattering pattern 470 and then enter the photodiode PD. In this way, as the incident light is scattered, an effective penetration depth of the incident light may be shortened, thereby improving the light collection efficiency of the incident light incident on the photodiode PD.

The wire region 20 may be positioned on the first surface 400a of the substrate 400 and include a plurality of insulating layers IL1, IL2, and IL3, a plurality of reflection members 460, a plurality of wiring layers CL1, and CL2, and a plurality of vias VIA.

The insulating layer may include a first insulating layer IL1, a second insulating layer IL2, and a third insulating layer IL3. The first insulating layer IL1, the second insulating layer IL2, and the third insulating layer IL3 may be sequentially laminated on the first surface 400a of the substrate 400.

The first insulating layer IL1 may cover or at least partially overlap the first surface 400a of the substrate 400. The first insulating layer IL1 may cover or at least partially overlap the first portion TGa of the transmission gate TG. The second insulating layer IL2 may be positioned on the first insulating layer IL1. The third insulating layer IL3 may be positioned on the second insulating layer IL2.

The first insulating layer to the third insulating layers IL1, IL2, and IL3 may include an insulating material. For example, the first insulating layer to third insulating layers IL1, IL2, and IL3 may include a silicon-based insulating material such as silicon oxide, silicon nitride or silicon oxidation nitride.

The wire region 20 may include a first wiring layer CL1 and a second wiring layer CL2. The first wiring layer CL1 may be positioned within the second insulating layer IL2. The second wiring layer CL2 may be positioned within the third insulating layer IL3.

The plurality of vias VIA may be positioned within the first insulating layer IL1, the second insulating layer IL2, and the third insulating layer IL3. The via VIA may connect the floating diffusion region FD, the first wiring layer CL1, and the second wiring layer CL2 to each other.

The first wiring layer CL1, the second wiring layer CL2, and the vias VIA may include a metal material. For example, the first wiring layer CL1, the second wiring layer CL2, and the vias VIA may include copper (Cu), aluminum (Al), tungsten (W), titanium (Ti), molybdenum (Mo), tantalum (Ta), titanium nitride layer (TiN), tantalum nitride layer (TaN), zirconium nitride layer (ZrN), tungsten nitride layer (WN), and an alloy composed of a combination thereof.

The plurality of reflection members 460 may be positioned within the first insulating layer IL1. The plurality of reflection members 460 may be positioned on the first surface 400a of the substrate 400 and be entirely covered or overlapped by the first insulating layer IL1.

The reflection member 460 may be positioned to overlap at least part of the photodiode isolation pattern 450. That is, the reflection member 460 may be positioned to overlap the photodiode isolation pattern 450 in the third direction Z perpendicular to the first surface 400a of the substrate 400. In other words, the center of the reflection member 460 may be positioned to coincide with the center of the photodiode isolation pattern 450.

In FIG. 3, the reflection member 460 is shown as overlapping the photodiode isolation pattern 450 in the third direction Z, but the overlap relationship between the reflection member 460 and the photodiode isolation pattern 450 in the third direction Z is not limited thereto and may be changed in various ways. For example, the reflection member 460 may be positioned to overlap a part of the photodiode isolation pattern 450 in the third direction Z. That is, the center of reflection member 460 may be positioned so as to be misaligned with the center of the photodiode isolation pattern 450.

Unlike as illustrated in FIG. 3, in some embodiments, the wire region 20 may further include a buffer layer (not shown) positioned between the reflection member 460 and the photodiode isolation pattern 450. That is, the buffer layer may be positioned between the first insulating layer IL1 and the first surface 400a of the substrate 400, and entirely cover or overlap the reflection member 460.

In this way, when the buffer layer entirely covering or overlapping the first surface 400a of the substrate 400 is further included, the transmission gate TG may extend into the substrate 400 through the buffer layer.

The width of the reflection member 460 along the first direction X may decrease as it moves away from the first surface 400a of the substrate 400 in the cross-sectional view. The width of the reflection member 460 in the first direction X adjacent to the first surface 400a of the substrate 400 may be greater than the width of the reflection member 460 in the first direction X adjacent to the second insulating layer IL2.

The reflection member 460 may include a side that is inclined or sloped with respect to the first surface 400a of the substrate 400. For example, the side of the reflection member 460 may include a reverse taper slope (e.g., the side of the reflection member 460 has a slope such that the width of the reflection member 460 gradually decreases from a second surface 460S2 to a first surface 460S1 of the reflection member 460). However, this is an example, and the shape of the cross-section of reflection member 460 may be changed in various ways. For example, the side of reflection member 460 may include a curved surface.

The reflection member 460 may include a conductive material. For example, the reflection member 460 may include a highly reflective metal material. As a more specific example, the reflection member 460 may include copper (Cu). However, this is an example, and the material included in the reflection member 460 may vary.

The reflection member 460 prevent or reduce a crosstalk by preventing the incident light incident on the photodiode PD from being reflected by the wiring layers CL1 and CL2 and/or the vias VIA and traveling to the adjacent pixels PX. That is, the reflection member 460 may perform the role of limiting the component of the incident light traveling to the adjacent pixels PX, and focusing the component of the incident light incident on one pixel PX, which is reflected or refracted to another pixel PX, onto the photodiode PD or the pixel PX.

The light transmitting layer 30 may be positioned on the second surface 400b of the substrate 400.

The light transmitting layer 30 may include an insulating structure 320, a grid pattern 310, and a micro lens layer MLL.

The light transmitting layer 30 may collect and filter the light incident from the outside and provide the light to the photodiodes PD.

The insulating structure 320 may be positioned between the second surface 400b of the substrate 400 and the grid pattern 310. The insulating structure 320 may prevent or inhibit the reflection of light so that the light incident on the second surface 400b of the substrate 400 may smoothly reach the photodiode PD. The insulating structure 320 may be referred to as an anti-reflection structure.

The insulating structure 320 may include a first fixing charge layer 321, a second fixing charge layer 323, and a planarization layer 325 sequentially stacked on the second surface 400b of the substrate 400.

As described above, the first fixing charge layer 321 of the insulating structure 320 may fill or be in a plurality of third trenches TR3 positioned adjacent to the second surface 400b of the substrate 400, and entirely cover or overlap the second surface 400b of the substrate 400. That is, the first fixing charge layer 321 positioned within the third trench TR3 may form the scattering pattern 470.

Each of the first fixing charge layer 321, the second fixing charge layer 323, and the planarization layer 325 may include different materials. The first fixing charge layer 321 may include at least one of aluminum oxide, tantalum oxide, titanium oxide, and hafnium oxide.

The second fixing charge layer 323 may include another one of aluminum oxide, tantalum oxide, titanium oxide, and/or hafnium oxide. For example, the first fixing charge layer 321 may include aluminum oxide, the second fixing charge layer 323 may include hafnium oxide, and the planarization layer 325 may include silicon oxide.

Although not shown in FIG. 3, in some embodiments, a silicon anti-reflection layer (not shown) may be positioned between the second fixing charge layer 323 and the planarization layer 325. The anti-reflection layer may include, for example, silicon nitride.

The grid pattern 310 may be positioned on the insulating structure 320. The grid pattern 310 may be positioned on the photodiode isolation pattern 450 and may overlap at least a portion of the photodiode isolation pattern 450 in the third direction Z. As shown in FIG. 2, the grid pattern 310 may be arranged in a lattice pattern on a plane. That is, the photodiode PD may be positioned between the adjacent grid patterns 310.

The grid pattern 310 may include at least one of a metal material, a metal nitride, and a material having a low refractive index. For example, the grid pattern 310 may include at least one of organic materials such as a polymer layer including titanium (Ti), titanium nitride (TiN), tungsten (W), aluminum (Al), copper (Cu), and silica nano particles. However, the material included in the grid pattern 310 is not limited to this and may be changed in various ways.

In FIG. 3, the grid pattern 310 is illustrated as including a single layer, but in some embodiments, the grid pattern 310 may include a plurality of layers. For example, the grid pattern 310 may be composed of multiple layers including two or more layers, and at least a portion of each layer included in grid pattern 310 may include the material described above.

The micro lens layer MLL may be positioned on the grid pattern 310 and the insulating structure 320. The micro lens layer MLL may include a flat portion MLP and a plurality of micro lenses ML sequentially stacked on the grid pattern 310 and the insulating structure 320.

The plurality of micro lenses ML and the flat portion MLP may include the same material and may be integrally formed. There may be no boundary between the plurality of micro lenses ML and the flat portion MLP.

The flat portion MLP of the micro lens layer MLL may entirely cover or overlap the grid pattern 310 and the insulating structure 320. The flat portion MLP may cover or overlap the entire upper surface of the insulating structure 320 positioned between the adjacent grid patterns 310. The flat portion MLP may cover or overlap the entire side and upper surface of the grid pattern 310. The upper surface of the flat portion MLP may be substantially flat.

In an embodiment, the thickness of the flat portion MLP along the third direction Z may be thicker than the thickness of the grid pattern 310 along the third direction Z. However, this is an example, and the thickness of the flat portion MLP may be substantially the same as the thickness of the grid pattern 310.

The plurality of micro lenses ML may be positioned on the flat portion MLP. The plurality of micro lenses ML may be positioned to correspond to of the plurality of pixels PX, respectively.

As shown in FIG. 2, the plurality of micro lenses ML may be arranged in two rows and two columns in the first to fourth pixel groups PG1, PG2, PG3, and PG4, respectively. That is, the number of the pixel PX and the number of the micro lens ML in each of the first to fourth pixel groups PG1, PG2, PG3, and PG4 may be substantially the same. However, the planar arrangement of the plurality of micro lenses ML is not limited to this and may be changed in various ways. For example, the plurality of micro lenses ML may be arranged to correspond to the first to fourth pixel groups PG1, PG2, PG3, and PG4, respectively. That is, the plurality of micro lenses ML may be arranged to correspond to four adjacent pixels PX arranged in two rows and two columns. As another example, the plurality of micro lenses ML may be arranged to correspond to nine adjacent pixels PX arranged in three rows and three columns.

The upper surface of the micro lens ML may include a convex surface to refract and focus light incident from the outside. However, the shape of the micro lens ML is not limited to this and may be changed in various ways. For example, the upper surface of the micro lens ML may have a quadrangle shape with rounded corners.

Although not shown in FIG. 3, in some embodiments, the light transmitting layer 30 may further include a color filter layer (not shown) positioned on the second surface 400b of the substrate 400 and including a plurality of color filters.

In some embodiments, when the light transmitting layer 30 further includes the color filter layer, the color filter layer may be positioned between the micro lens layer MLL and the grid pattern 310 and between the micro lens layer MLL and the insulating structure 320.

In some embodiments, where the light transmitting layer 30 further includes the color filter layer including the plurality of color filters, the grid pattern 310 may be positioned at a boundary between the plurality of color filters and may entirely surround or extend around the plurality of color filters. That is, the grid pattern 310 may separate the plurality of adjacent color filters.

The plurality of color filters included in the color filter layer may entirely cover or overlap the side and upper surfaces of the grid pattern 310. The plurality of color filters may cover or overlap the entire upper surface of the insulating structure 320 positioned between the grid patterns 310.

More specifically, the color filter layer may include the plurality of color filters arranged along rows and columns to correspond to the plurality of pixels PX, respectively. For example, the plurality of color filters may include a red color filter, a green color filter, and a blue color filter. As another example, the plurality of color filters may include a cyan color filter, a magenta color filter, and a yellow color filter.

Hereinafter, the photodiode isolation pattern 450 is described in further detail with reference to FIG. 4.

FIG. 4 is an enlarged view of a region P1 of FIG. 3.

Referring to FIG. 3 and FIG. 4, in an embodiment, the width of the photodiode isolation pattern 450 along the first direction X may gradually decrease from the first surface 400a of the substrate 400 to the second surface 400b. That is, the width in the first direction X of the end of the photodiode isolation pattern 450 adjacent to the first surface 400a of the substrate 400 may be larger than the width in the first direction X of the end of the photodiode isolation pattern 450 adjacent to the second surface 400b of the substrate 400.

Accordingly, the photodiode isolation pattern 450 may include a sloped side surface with respect to the second surface 400b of the substrate 400. The side of the photodiode isolation pattern 450 may have a reverse taper slope (e.g., the side of the photodiode isolation pattern 450 has a slope such that the width of the photodiode isolation pattern 450 gradually increases from a second surface 460S2 to a first surface 460S1 of the photodiode isolation pattern 450).

The width of the insulating isolation pattern 451 along the first direction X may gradually decrease from the first surface 400a of the substrate 400 to the second surface 400b. That is, the width in the first direction X of the end of the insulating isolation pattern 451 adjacent to the first surface 400a of the substrate 400 may be larger than the width in the first direction X of the end of the insulating isolation pattern 451 adjacent to the second surface 400b of the substrate 400.

Accordingly, the insulating isolation pattern 451 may include the sloped side surface 451S3 with respect to the second surface 400b of the substrate 400. The side surface 451S3 of the insulating isolation pattern 451 may have a reverse taper slope (e.g., the side surface 451S3 has a slope such that the width of the insulating isolation pattern 451 gradually increases from a second surface 451S2 to a first surface 451S1 of insulating isolation pattern 451).

The insulating isolation pattern 451 may include a first surface 451S1 adjacent to the first surface 400a of the substrate 400 and a second surface 451S2 adjacent to the second surface 400b of the substrate 400. The insulating isolation pattern 451 may have a maximum width in the first direction X at the first surface 451S1 and a minimum width in the first direction X at the second surface 451S2.

The first surface 451S1 of the insulating isolation pattern 451 may be in contact with the first surface 400a of the substrate 400 or the first insulating layer IL1, and the second surface 451S2 of the insulating isolation pattern 451 may be in contact with the second surface 400b of the substrate 400 or the first fixing charge layer 321.

In FIG. 3 and FIG. 4, it is shown that the first surface 451S1 of the insulating isolation pattern 451 and the first surface 400a of the substrate 400 are flat, and the second surface 451S2 of the insulating isolation pattern 451 and the second surface 400b of the substrate 400 are flat, but in some embodiments, the first surface 451S1 of the insulating isolation pattern 451 and the first surface 400a of the substrate 400 may be curved, and the second surface 451S2 of the insulating isolation pattern 451 and the second surface 400b of the substrate 400 may be curved. That is, the first surface 451S1 of the insulating isolation pattern 451 may be positioned at a different level in the third direction Z from the first surface 400a of the substrate 400, and the second surface 451S2 of the insulating isolation pattern 451 and the second surface 400b of the substrate 400 may be positioned at a different level in the third direction Z.

The first surface 451S1 of the insulating isolation pattern 451 may have a first width W1 along the first direction X, and the second surface 451S2 may have a second width W2 along the first direction X. The first width W1 may be larger than the second width W2. For example, the ratio of the first width W1 to the second width W2 may be about 1.5:1 to about 3:1. However, this is an example and the ratio of the first width W1 and the second width W2 may be changed in various ways.

The conductive isolation pattern 453 may include a first surface 453S1 adjacent to the first surface 400a of the substrate 400 and a second surface 453S2 adjacent to the second surface 400b of the substrate 400. The first surface 453S1 of the conductive isolation pattern 453 may be in contact with the buried insulating pattern 455, and the second surface 453S2 of the conductive isolation pattern 453 may be in contact with the second surface 400b of the substrate 400 or the first fixing charge layer 321.

In FIG. 3 and FIG. 4, the second surface 453S2 of the conductive isolation pattern 453 and the second surface 400b of the substrate 400 are shown as being flat, but in some embodiments, the second surface 453S2 of the conductive isolation pattern 453 and the second surface 400b of the substrate 400 may have a curvature. That is, the second surface 453S2 of the conductive isolation pattern 453 and the second surface 400b of the substrate 400 may be positioned at different levels in the third direction Z.

The width of the conductive isolation pattern 453 along the first direction X adjacent to the first surface 400a of the substrate 400 may be greater than the width of the conductive isolation pattern 453 along the first direction X adjacent to the second surface 400b of the substrate 400. The conductive isolation pattern 453 may have a maximum width in the first direction X at the first surface 453S1 and a minimum width in the first direction X at the second surface 453S2.

The length of the conductive isolation pattern 453 along the third direction Z may be smaller than the length of the insulating isolation pattern 451 along the third direction Z. That is, the first surface 453S1 of the conductive isolation pattern 453 may be positioned at a higher level than the first surface 451S1 of the insulating isolation pattern 451 relative to the first surface 400a in the third direction Z. In other words, the first surface 453S1 of the conductive isolation pattern 453 may be positioned closer to the second surface 400b of the substrate 400 than the first surface 451S1 of the insulating isolation pattern 451.

The first surface 453S1 of the conductive isolation pattern 453 may have a third width W3 along the first direction X, and the second surface 453S2 may have a fourth width W4 along the first direction X. The third width W3 may be larger than the fourth width W4. For example, the third width W3 may be up to about 1.05 times greater than the fourth width W4. That is, the ratio of the third width W3 to the fourth width W4 may be less than or equal to about 1.05:1. However, this is an example and the ratio of the third width W3 to the fourth width W4 may be changed in various ways.

In an embodiment, the maximum width in the first direction X of the conductive isolation pattern 453 may be greater than the maximum width in the first direction X of the insulating isolation pattern 451, and the minimum width in the first direction X of the conductive isolation pattern 453 may be greater than the minimum width in the first direction X of the insulating isolation pattern 451. That is, the width of the first surface 453S1 of the conductive isolation pattern 453 along the first direction X may be larger than the width of the first surface 451S1 of the insulating isolation pattern 451 along the first direction X, and the width of the second surface 453S2 of the conductive isolation pattern 453 along the first direction X may be greater than the width of the second surface 451S2 of the insulating isolation pattern 451 along the first direction X. In other words, the third width W3 may be larger than the first width W1, and the fourth width W4 may be larger than the second width W2.

In some embodiments, the maximum width in the first direction X of the conductive isolation pattern 453 may be less than the maximum width in the first direction X of the insulating isolation pattern 451, and the minimum width in the first direction X of the conductive isolation pattern 453 may be greater than the minimum width in the first direction X of the insulating isolation pattern 451. That is, the width of the first surface 453S1 of the conductive isolation pattern 453 along the first direction X may be smaller than the width of the first surface 451S1 of the insulating isolation pattern 451 along the first direction X, and the width of the second surface 453S2 of the conductive isolation pattern 453 along the first direction X may be larger than the width of the second surface 451S2 of the insulating isolation pattern 451 along the first direction X. In other words, the third width W3 may be smaller than the first width W1, and the fourth width W4 may be larger than the second width W2.

The buried insulating pattern 455 may include a first surface 455S1 and a second surface 455S2 facing each other in the third direction Z.

The first surface 455S1 of the buried insulating pattern 455 may be in contact with the first surface 400a of the substrate 400 or the first insulating layer IL1, and the second surface 455S2 of the buried insulating pattern 455 may be in contact with the first surface 453S1 of the conductive isolation pattern 453.

In FIG. 3 and FIG. 4, the first surface 455S1 of the buried insulating pattern 455 and the first surface 400a of the substrate 400 are shown as being flat, but in some embodiments, the first surface 455S1 of the buried insulating pattern 455 and the first surface 400a of the substrate 400 may have a curvature. That is, the first surface 455S1 of the buried insulating pattern 455 and the first surface 400a of the substrate 400 may be positioned at different levels in the third direction Z.

The length of the buried insulating pattern 455 along the third direction Z may be smaller than the length of the conductive isolation pattern 453 along the third direction Z. The length of the buried insulating pattern 455 along the third direction Z may be greater than the length of the element isolation pattern 403 along the third direction Z.

One surface of the element isolation pattern 403 adjacent to the second surface 455S2 of the buried insulating pattern 455 may be positioned at a lower level in the third direction Z than the second surface 455S2 of the buried insulating pattern 455. That is, one surface of the element isolation pattern 403 may be positioned closer to the first surface 400a of the substrate 400 than to the second surface 455S2 of the buried insulating pattern 455.

The first surface 455S1 of the buried insulating pattern 455 may have a fifth width W5 along the first direction X, and the second surface 455S2 may have a third width W3 along the first direction X. That is, the second surface 455S2 of the buried insulating pattern 455 in contact with the conductive isolation pattern 453 have the width substantially the same as the first surface 453S1 of the conductive isolation pattern 453.

In an embodiment, the third width W3 and the fifth width W5 may be substantially the same. Accordingly, the ratio of the fifth width W5 to the fourth width W4 may be substantially the same as the ratio of the third width W3 to the fourth width W4. However, the relationship between the third width W3 and the fifth width W5 may be changed in various ways. For example, the fifth width W5 may be larger than third width W3.

Here, “same” may mean not only something that is completely the same, but also something that includes fine differences that may occur due to a process margin, etc.

In an embodiment, the first width W1 may be smaller than the fifth width W5. However, the relationship between the first width W1 and the fifth width W5 is not limited to this and may be changed in various ways. For example, the first width W1 may be larger than the fifth width W5.

In an embodiment, the photodiode isolation pattern 450 may include a first surface 450S1 adjacent to the first surface 400a of the substrate 400 and a second surface 450S2 adjacent to the second surface 400b of the substrate 400. The photodiode isolation pattern 450 may have a maximum width in the first direction X at the first surface 450S1 and a minimum width in the first direction X at the second surface 450S2.

The first surface 450S1 of the photodiode isolation pattern 450 may be in contact with the first surface 400a of the substrate 400 or the first insulating layer IL1, and the second surface 450S2 of the photodiode isolation pattern 450 may be in contact with the second surface 400b of the substrate 400 or the first fixing charge layer 321.

The first surface 450S1 of the photodiode isolation pattern 450 may include a first surface 451S1 of the insulating isolation pattern 451 and a first surface 455S1 of the buried insulating pattern 455. The second surface 450S2 of the photodiode isolation pattern 450 may include a second surface 451S2 of the insulating isolation pattern 451 and a second surface 453S2 of the conductive isolation pattern 453.

In FIG. 3 and FIG. 4, the first surface 450S1 of the photodiode isolation pattern 450 and the first surface 400a of the substrate 400 are shown as flat, and the second surface 450S2 of the photodiode isolation pattern 450 and the second surface 400b of the substrate 400 are shown as flat, but the first surface 450S1 of the photodiode isolation pattern 450 and the first surface 400a of the substrate 400 may have curvatures, and the second surface 450S2 of the photodiode isolation pattern 450 and the second surface 400b of the substrate 400 may have curvatures. That is, the first surface 450S1 of the photodiode isolation pattern 450 may be positioned at a different level in the third direction Z from the first surface 400a of the substrate 400, and the second surface 450S2 of the photodiode isolation pattern 450 and the second surface 400b of the substrate 400 may be positioned at different levels in the third direction Z.

In an embodiment, the first surface 450S1 of the photodiode isolation pattern 450 may have a sixth width W6 along the first direction X, and the second surface 450S2 may have a seventh width W7 along the first direction X.

Here, the sixth width W6 may be substantially the same as the sum of the fifth width W5 of the first surface 455S1 of the buried insulating pattern 455 and the first width W1 of the first surfaces 451S1 of the insulating isolation pattern 451 positioned on both sides of the buried insulating pattern 455.

The seventh width W7 may be substantially the same as the sum of the fourth width W4 of the second surface 453S2 of the conductive isolation pattern 453 and the second width W2 of the second surfaces 451S2 of the insulating isolation pattern 451 positioned on both sides of the conductive isolation pattern 453.

Here, “same” may mean not only something that is completely the same, but also something that includes fine differences that may occur due to process margins, etc.

The sixth width W6 may be larger than the seventh width W7. For example, the ratio of the sixth width W6 to the seventh width W7 may be about 1.2:1 to about 2:1. However, this is an example and the ratio of the sixth width W6 to the seventh width W7 may be changed in various ways.

In an embodiment, the first width W1 and the second width W2 of the insulating isolation pattern 451, the third width W3 of the conductive isolation pattern 453 and the buried insulating pattern 455, the fourth width W4 of the conductive isolation pattern 453, the fifth width W5 of the buried insulating pattern 455, and the ratio between the sixth width W6 and the seventh width W7 of the photodiode isolation pattern 450 have the above-described numerical ranges, the photodiode isolation pattern 450 positioned between the plurality of photodiodes PD may have the shape of the photodiode isolation pattern 450 that may prevent or inhibit a reduction in the size of the pixel PX and simultaneously prevent or reduce a crosstalk phenomenon.

In an embodiment, the side surface 451S3 of the insulating isolation pattern 451 may form a first angle θ1 with the second surface 400b of the substrate 400, and the side surface 453S3 of the conductive isolation pattern 453 may form a second angle θ2 with the second surface 400b of the substrate 400. For example, the second angle θ2 may be larger than the first angle θ1. Accordingly, the slope of the side surface 453S3 of the conductive isolation pattern 453 may be steeper or greater than the slope of the side surface 451S3 of the insulating isolation pattern 451.

Here, the first angle θ1 may refer to an angle measured from the second surface 400b of the substrate 400 along the counterclockwise direction to the side surface 451S3 of the insulating isolation pattern 451, and the second angle θ2 may refer to an angle measured from the second surface 400b of the substrate 400 along the counterclockwise direction to the side surface 451S3 of the conductive isolation pattern 453.

The reflection member 460 may include a first surface 460S1 and a second surface 460S2 facing each other in the third direction Z. The first surface 460S1 of the reflection member 460 may be positioned within the first insulating layer IL1, and the second surface 460S2 may be in contact with the first surface 400a of the substrate 400 or the upper surface of the first insulating layer IL1.

The first surface 460S1 of the reflection member 460 may have an eighth width W8 along the first direction X, and the second surface 460S2 may have a sixth width W6 along the first direction X. That is, the second surface 460S2 of the reflection member 460 may have a width substantially the same as that of the first surface 450S1 of the photodiode isolation pattern 450 along the first direction X. The sixth width W6 may be larger than the eighth width W8. However, this is an example, and the relationship between the sixth width W6 and the eighth width W8 may be changed in various ways.

In addition, in FIG. 3 and FIG. 4, the width of the second surface 460S2 of the reflection member 460 and the width of the first surface 450S1 of the photodiode isolation pattern 450 are shown as being substantially the same, but the relationship between the width of the second surface 460S2 of the reflection member 460 and the width of the first surface 450S1 of the photodiode isolation pattern 450 may be changed in various ways. For example, the width of the second surface 460S2 of the reflection member 460 may be smaller than the width of the first surface 450S1 of the photodiode isolation pattern 450. That is, the maximum width in the first direction X of reflection member 460 may be smaller than the maximum width in the first direction X of photodiode isolation pattern 450. Here, “same” can mean not only something that is completely the same, but also something that includes fine differences that may occur due to process margins, etc.

In some embodiments, as the width of the insulating isolation pattern 451 included in the photodiode isolation pattern 450 positioned between the plurality of photodiodes PD decreases toward the light-receiving surface of the substrate 400, it is possible to prevent or reduce the crosstalk phenomenon by preventing the size of the pixel PX from decreasing and simultaneously preventing the incident light incident on the photodiode PD from passing through the photodiode isolation pattern 450 and incident on the adjacent pixel PX.

In addition, according to an embodiment, the image sensor includes the reflection member 460 positioned to overlap the photodiode isolation pattern 450, thereby preventing or reducing crosstalk by preventing the incident light incident on the photodiode PD from being reflected by the wiring layers CL1 and CL2 and/or vias VIA and traveling to the adjacent pixel PX.

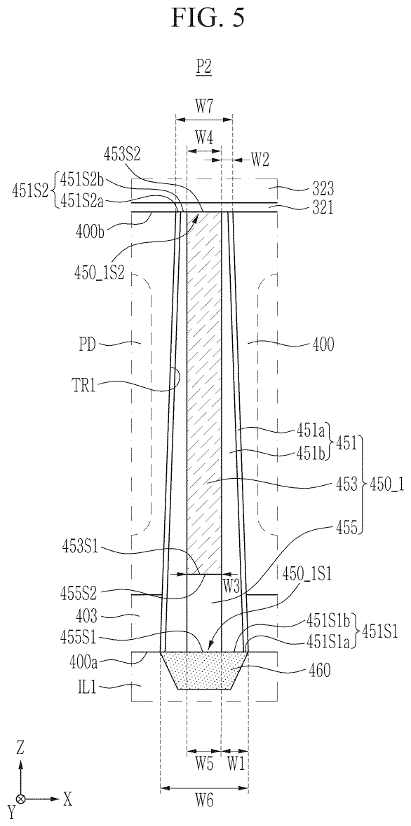

Hereinafter, the image sensors according to various embodiments are described with reference to FIG. 5 to FIG. 12. In the embodiments below, the same components as those described previously are referred to by the same reference numerals, and duplicate descriptions are omitted or simplified, with explanations focusing on differences.

FIG. 5 to FIG. 11 are cross-sectional views showing a cross-section of an image sensor according to some embodiments. Specifically, FIG. 5 to FIG. 11 are partial enlarged views illustrating regions P2 to P8 corresponding to the region P1 of FIG. 3 according to some embodiments.

The photodiode isolation pattern 450_1 according to the embodiments illustrated in FIG. 5 is different from the photodiode isolation pattern 450 according to the embodiments illustrated in FIG. 4 in that the insulating isolation pattern 451 is composed of a plurality of layers.

Specifically, referring to FIG. 5, the insulating isolation pattern 451 of photodiode isolation pattern 450_1 may include a first insulating isolation pattern 451a extending along an inner side wall of a first trench TR1 and a second insulating isolation pattern 451b positioned on the first insulating isolation pattern 451a. The second insulating isolation pattern 451b may be positioned between the first insulating isolation pattern 451a and the conductive isolation pattern 453 and between the first insulating isolation pattern 451a and the buried insulating pattern 455.

In the present embodiments, the first insulating isolation pattern 451a and the second insulating isolation pattern 451b may include the same material. For example, the first insulating isolation pattern 451a and the second insulating isolation pattern 451b may include silicon-based insulating materials (e.g., silicon oxide) having different compositions.

This may be a result of the first insulating isolation pattern 451a and the second insulating isolation pattern 451b being formed through different process steps, and the precursor materials used in the process steps forming each of them being different. However, this is an example, and the first insulating isolation pattern 451a and the second insulating isolation pattern 451b may include different materials. For example, the first insulating isolation pattern 451a and the second insulating isolation pattern 451b may include different silicon-based insulating materials.

The first insulating isolation pattern 451a may include a first surface 451S1a in contact with the first surface 400a of the substrate 400 and a second surface 451S2a in contact with the second surface 400b of the substrate 400.

In the present embodiments, the width of the first surface 451S1a of the first insulating isolation pattern 451a along the first direction X may be greater than the width of the second surface 451S2a along the first direction X. The first insulating isolation pattern 451a may have the maximum width in the first direction X at the first surface 451S1a and the minimum width in the first direction X at the second surface 451S2a.

The second insulating isolation pattern 451b may include a first surface 451S1b in contact with the first surface 400a of the substrate 400 and a second surface 451S2b in contact with the second surface 400b of the substrate 400.

The width of the first surface 451S1b of the second insulating isolation pattern 451b along the first direction X may be greater than the width of the second surface 451S2b along the first direction X. The second insulating isolation pattern 451b may have the maximum width in the first direction X at the first surface 451S1b and the minimum width in the first direction X at the second surface 451S2b.

In the present embodiments, the width of the first insulating isolation pattern 451a along the first direction X may be different from the width of the second insulating isolation pattern 451b along the first direction X.

Specifically, the width of the first surface 451S1a of the first insulating isolation pattern 451a along the first direction X may be smaller than the width of the first surface 451S1b of the second insulating isolation pattern 451b along the first direction X.

The width of the second surface 451S2a of the first insulating isolation pattern 451a along the first direction X may be smaller than the width of the second surface 451S2b of the second insulating isolation pattern 451b along the first direction X. That is, the maximum width of the first insulating isolation pattern 451a may be smaller than the maximum width of the second insulating isolation pattern 451b, and the minimum width of the first insulating isolation pattern 451a may be smaller than the minimum width of the second insulating isolation pattern 451b.

In this way, the difference in the width or the thickness between the first insulating isolation pattern 451a and the second insulating isolation pattern 451b may be a result of forming the first insulating isolation pattern 451a and the second insulating isolation pattern 451b separately by different processes.

As shown in FIG. 5, the first surface 451S1 of the insulating isolation pattern 451 included in the photodiode isolation pattern 450_1 may include the first surface 451S1a of the first insulating isolation pattern 451a and the first surface 451S1b of the second insulating isolation pattern 451b, and the second surface 451S2 of the insulating isolation pattern 451 may include the second surface 451S2a of the first insulating isolation pattern 451a and the second surface 451S2b of the second insulating isolation pattern 451b.

The first surface 450_1S1 of the photodiode isolation pattern 450_1 may include a first surface 451S1a of the first insulating isolation pattern 451a, a first surface 451S1b of the second insulating isolation pattern 451b, and a first surface 455S1 of the buried insulating pattern 455.

The second surface 450_1S2 of the photodiode isolation pattern 450_1 may include a second surface 451S2a of the first insulating isolation pattern 451a, a second surface 451S2b of the second insulating isolation pattern 451b, and a second surface 455S2 of the buried insulating pattern 455.

For the relationship of the first width W1 and the second width W2 of the insulating isolation pattern 451 shown in FIG. 5, the third width W3 of the conductive isolation pattern 453 and the buried insulating pattern 455, the fourth width W4 of the conductive isolation pattern 453, the fifth width W5 of the buried insulating pattern 455, and the sixth width W6 and the seventh width W7 of the photodiode isolation pattern 450_1 and the numerical range of the ratios thereof, the explanation described in FIG. 4 may be applied substantially the same, and thus the detailed descriptions thereof are omitted.

According to the embodiments illustrated in FIG. 5, in the process of forming the photodiode isolation pattern 450_1, by sequentially forming the first insulating isolation pattern 451a and the second insulating isolation pattern 451b constituting the insulating isolation pattern 451 within the first trench TR1, the insulating isolation pattern 451 formed within the first trench TR1 may not include a void.

Accordingly, by evenly forming the insulating isolation pattern 451 within the first trench TR1, a crosstalk phenomenon between the adjacent pixels may be effectively prevented or reduced.

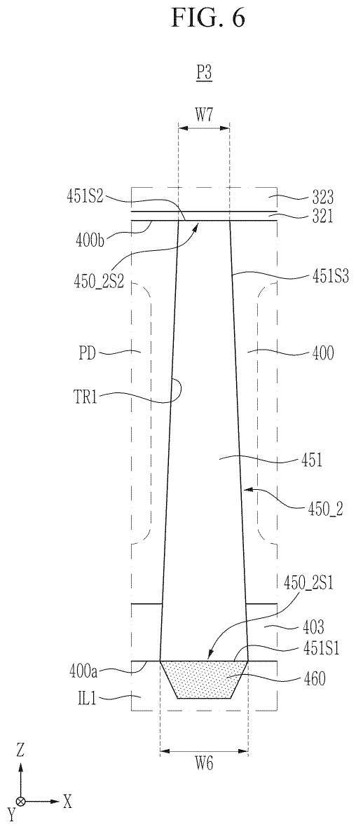

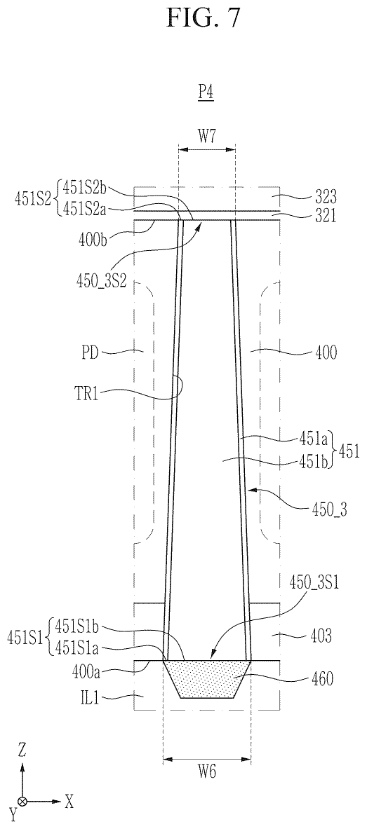

According to photodiode isolation patterns 450_2 and 450_3 according to the embodiments illustrated in FIG. 6 and FIG. 7, there is a difference in that the conductive isolation pattern 453 is omitted, unlike the photodiode isolation pattern 450 according to the embodiments illustrated in FIG. 4.

Referring to FIG. 6, in the present embodiments, the photodiode isolation pattern 450_2 includes an insulating isolation pattern 451, and may not include a conductive isolation pattern (see ‘453’ of FIG. 4) and a buried insulating pattern (see ‘455’ of FIG. 4).

The photodiode isolation pattern 450_2 according to the present embodiment may be formed by at least partially filling an insulating isolation pattern 451 including an insulating material within the first trench TR1, and may not form a conductive isolation pattern 453 within the first trench TR1. Accordingly, the photodiode isolation pattern 450_2 according to the present embodiment may be made only of the insulating material.

Additionally, in the present embodiments, since the photodiode isolation pattern 450_2 does not include the conductive isolation pattern 453, the buried insulating pattern 455 that entirely covers or overlaps the conductive isolation pattern 453 may not be formed.

Specifically, the insulating isolation pattern 451 included in the photodiode isolation pattern 450_2 according to the present embodiment may include a first surface 451S1 in contact with the first surface 400a of the substrate 400 and a second surface 451S2 in contact with the second surface 400b of the substrate 400.

The first surface 451S1 of the insulating isolation pattern 451 may form the first surface 450_2S1 of the photodiode isolation pattern 450_2, and the second surface 451S2 of the insulating isolation pattern 451 may form the second surface 450_2S2 of the photodiode isolation pattern 450_2. The photodiode isolation pattern 450_2 may have the maximum width in the first direction X at the first surface 450_2S1 and the minimum width in the first direction X at the second surface 450_2S2.

In the present embodiments, the first surface 450_2S1 of the photodiode isolation pattern 450_2 may have a sixth width W6 along the first direction X, and the second surface 450_2S2 may have a seventh width W7 along the first direction X. The sixth width W6 may be larger than the seventh width W7. For example, the ratio of the sixth width W6 to the seventh width W7 may be about 1.2:1 to about 2:1. However, this is an example and the ratio of the sixth width W6 to the seventh width W7 may be changed in various ways.

The insulating isolation pattern 451 included in the photodiode isolation pattern 450_3 according to the embodiments illustrated in FIG. 7 may be composed of a plurality of layers, unlike the insulating isolation pattern 451 included in the photodiode isolation pattern 450_2 according to the embodiments illustrated in FIG. 6.

Specifically, referring to FIG. 7, the insulating isolation pattern 451 included in photodiode isolation pattern 450_3 may include a first insulating isolation pattern 451a and a second insulating isolation pattern 451b, similar to the insulating isolation pattern 451 included in photodiode isolation pattern 450_1 according to the embodiments illustrated in FIG. 5.

Referring to FIG. 5, the contents of the first insulating isolation pattern 451a and the second insulating isolation pattern 451b described above may be substantially the same applied to the first insulating isolation pattern 451a and the second insulating isolation pattern 451b according to the embodiments illustrated in FIG. 7, and therefore, hereinafter, the differences from the embodiments illustrated in FIG. 5 will be mainly explained.

Unlike the embodiments shown in FIG. 6, in the present embodiments, the first surface 450_3S1 of the photodiode isolation pattern 450_3 may include the first surface 451S1a of the first insulating isolation pattern 451a and the first surface 451S1b of the second insulating isolation pattern 451b, and the second surface 450_3S2 of the photodiode isolation pattern 450_3 may include the second surface 451S2a of the first insulating isolation pattern 451a and the second surface 451S2b of the second insulating isolation pattern 451b.

The first surface 450_3S1 of photodiode isolation pattern 450_3 may have the sixth width W6 along the first direction X, and the second surface 450_3S2 may have the seventh width W7 along the first direction X. The above contents referred to FIG. 6 may be substantially the same applied to the relationship between the sixth width W6 and the seventh width W7 and the numerical range of their ratios as and thus detailed descriptions thereof are omitted.

The width of the insulating isolation pattern 451 included in the photodiode isolation patterns 450_2 and 450_3 by the embodiments shown in FIG. 6 and FIG. 7 is relatively large compared with the width of the insulating isolation pattern 451 included in the photodiode isolation pattern 450 according to the embodiments illustrated in FIG. 4, thereby effectively preventing or reducing the crosstalk phenomenon between the adjacent pixels.

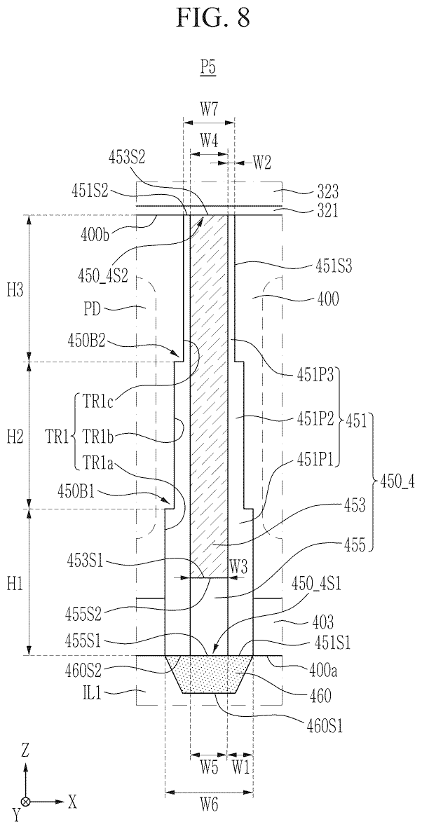

The photodiode isolation patterns 450_4, 450_5, and 450_6 according to the embodiments illustrated in FIG. 8 to FIG. 10 have different shapes from the photodiode isolation pattern 450 illustrated in FIG. 5.

The description of the conductive isolation pattern 453 and the buried insulating pattern 455 included in the photodiode isolation pattern 450 according to embodiment illustrated in FIG. 4 may be applied substantially equally to the conductive isolation pattern 453 and the buried insulating pattern 455 included in the photodiode isolation patterns 450_4, 450_5, and 450_6) according to the embodiments illustrated in FIG. 8 to FIG. 10 and thus a description thereof is omitted.

Hereinafter, differences of the insulating isolation pattern 451 included in the photodiode isolation pattern 450 according to the embodiments shown in FIG. 4 and the insulating isolation pattern 451 included in the photodiode isolation patterns 450_4, 450_5, and 450_6 according to the embodiments shown in FIG. 8 to FIG. 10 are mainly described.

Specifically, the insulating isolation pattern 451 included in the photodiode isolation patterns 450_4, 450_5, and 450_6 according to the embodiments illustrated in FIG. 8 to FIG. 10 may include a first portion 451P1, a second portion 451P2, and a third portion 451P3 sequentially positioned on the first surface 400a and the second surface 400b of the substrate 400 and having different widths in the first direction X. However, this is an example only, and the insulating isolation pattern 451 may include two portions having different widths, or may include four or more portions having different widths.

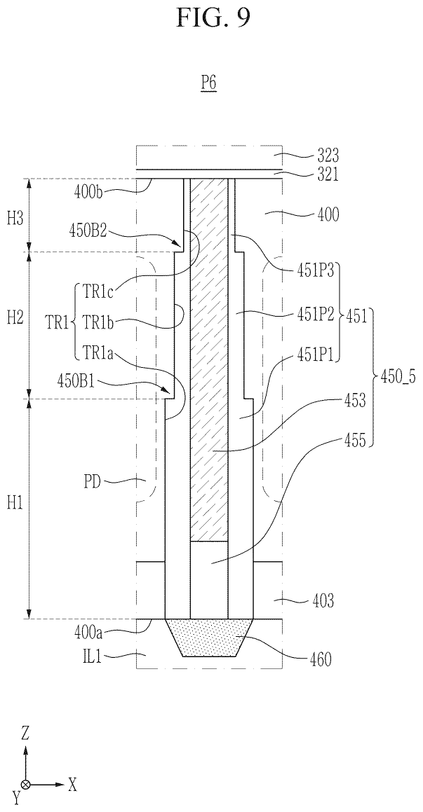

As shown in FIG. 8 and FIG. 9, the first trench TR1 may include a first portion TR1a, a second portion TR1b, and a third portion TR1c sequentially positioned between the first surface 400a and the second surface 400b of the substrate 400.

The widths of the first portion TR1a, the second portion TR1b, and the third portion TR1c of the first trench TR1 along the first direction X may be different. For example, the width of the first portion TR1a of the first trench TR1 may be greater than the width of the second portion TR1b, and the width of the second portion TR1b may be greater than the width of the third portion TR1c.

In addition, the maximum and minimum widths of the first portion TR1a of the first trench TR1 along the first direction X may be substantially the same, the maximum and minimum widths of the second portion TR1b along the first direction X may be substantially the same, and the maximum and minimum widths of the third portion TR1c along the first direction X may be substantially the same. Here, “same” may mean not only something that is completely the same, but also something that includes fine differences that may occur due to process margins, etc.

As shown in FIG. 8 and FIG. 9, each of the first portion TR1a, the second portion TR1b, and the third portion TR1c of the first trench TR1 may have a quadrangle shape in a cross-sectional view. However, the cross-sectional shape of each of the first portion TR1a, the second portion TR1b, and the third portion TR1c of the first trench TR1 is not limited thereto and may be changed in various ways. For example, the side surfaces of the first portion TR1a, the second portion TR1b, and the third portion TR1c of the first trench TR1 may include a curved surface.

The first portion 451P1 of the insulating isolation pattern 451 may be positioned within the first portion TR1a of the first trench TR1, the second portion 451P2 may be positioned within the second portion TR1b of the first trench TR1, and the third portion 451P3 can be positioned within the third portion TR1c of the first trench TR1. The first portion 451P1, the second portion 451P2, and the third portion 451P3 of the insulating isolation pattern 451 may be formed integrally.

The buried insulating pattern 455 included in the photodiode isolation patterns 450_4, 450_5, and 450_6 according to the embodiments illustrated in FIG. 8 to FIG. 10 may be positioned within the first portion TR1a of the first trench TR1. Additionally, the conductive isolation pattern 453 included in the photodiode isolation patterns 450_4, 450_5, and 450_6 may be positioned on the first portion TR1a, the second portion TR1b, and the third portion TR1c of the first trench TR1.

Since the widths of the first portion TR1a, the second portion TR1b, and the third portion TR1c of the first trench TR1 along the first direction X are different, the widths of the first portion 451P1, the second portion 451P2, and the third portion 451P3 of the insulating isolation pattern 451 positioned at each of these may be different along the first direction X.

Referring to FIG. 8 to FIG. 10, the width in the first direction X of the first portion 451P1 of the insulating isolation pattern 451 may be larger than the width in the first direction X of the second portion 451P2, and the width of the second portion 451P2 of the insulating isolation pattern 451 may be larger than the width of the third portion 451P3 of the insulating isolation pattern 451.

The insulating isolation pattern 451 may have the maximum width along the first direction X in the first portion 451P1 and the minimum width along the first direction X in the third portion 451P3.

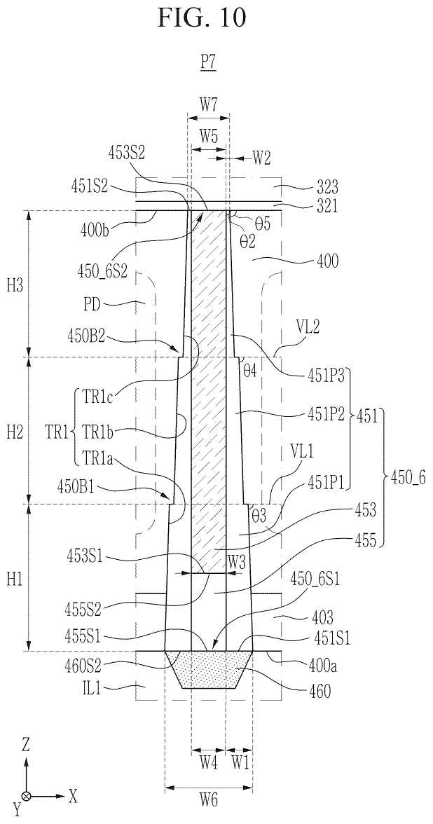

As shown in FIG. 8 and FIG. 10, the first portion 451P1 of the insulating isolation pattern 451 in contact with the first surface 400a of the substrate 400 may constitute the first surface 451S1 of the insulating isolation pattern 451 and has the first width W1 along the first direction X, and the third portion 451P3 of the insulating isolation pattern 451 in contact with the second surface 400b of the substrate 400 may constitute the second surface 451S2 of the insulating isolation pattern 451 and have the second width W2 along the first direction X.

According to embodiments illustrated in FIG. 8, the first surface 450_4S1 of the photodiode isolation pattern 450_4 may include a first surface 451S1 of the insulating isolation pattern 451 and a first surface 455S1 of the buried insulating pattern 455, and the second surface 450_4S2 may include a second surface 451S2 of the insulating isolation pattern 451 and a second surface 453S2 of the conductive isolation pattern 453.

In FIG. 8, the numerical range for the first width W1 and the second width W2 of the insulating isolation pattern 451, the third width W3 of the conductive isolation pattern 453 and the buried insulating pattern 455, the fourth width W4 of the conductive isolation pattern 453, the fifth width W5 of the buried insulating pattern 455, and the relationship of the sixth width W6 and the seventh width W7 of the photodiode isolation pattern 450_4 and the ratio thereof may be substantially equally applied with the content described with reference to FIG. 4 and thus the detail descriptions thereof are omitted.

The sides of the photodiode isolation patterns 450_4, 450_5, and 450_6 according to embodiments illustrated in FIG. 8 to FIG. 10 may include at least one bend portion 450B1 and 450B2, unlike the photodiode isolation pattern 450 according to the embodiments illustrated in FIG. 4.

In the embodiments shown in FIG. 8 to FIG. 10, since the first trench TR1, where the photodiode isolation patterns 450_4, 450_5, and 450_6 are positioned, includes the first portion TR1a, the second portion TR1b, and the third portion TR1c have the different widths along the first direction X, the side surfaces of the photodiode isolation patterns 450_4, 450_5, and 450_6 may include the bend portions 450B1 and 450B2. That is, the side surface 451S3 of the insulating isolation pattern 451 constituting the side surface of the photodiode isolation patterns 450_4, 450_5, and 450_6 may include the plurality of bend portions 450B1 and 450B2.

Specifically, the side surface 451S3 of the insulating isolation pattern 451 may include a first bend portion 450B1 positioned at a portion where the first portion 451P1 and the second portion 451P2 of the insulating isolation pattern 451 are connected, and a second bend portion 450B2 positioned at a location where the second portion 451P2 and the third portion 451P3 of the insulating isolation pattern 451 are connected. However, this is an example, and the number of the bend portions included in the side surface 451S3 of the insulating isolation pattern 451 may vary. For example, the side surface 451S3 of the insulating isolation pattern 451 may include one bend, or three or more bends.

Accordingly, since the side surface 451S3 of the insulating isolation pattern 451 includes the bent portions 450B1 and 450B2, the first portion 451P1 and the second portion 451P2 of the insulating isolation pattern 451 may have a step, and the second portion 451P2 and the third portion 451P3 of the insulating isolation pattern 451 may have a step. That is, the side surface 451S3 of the insulating isolation pattern 451 may have a step shape in a cross-sectional view.

In FIG. 8 to FIG. 10, the bends 450B1 and 450B2 of the photodiode isolation patterns 450_4, 450_5, and 450_6 are shown as having an angular shape or stepped shape, but the shape of the bends 450B1 and 450B2 is not limited thereto and may be variously changed in the process of forming the first trench TR1. For example, since the bend portions 450B1 and 450B2 have a rounded shape in a cross-section, the bend portions 450B1 and 450B2 may include curved surfaces. As another example, one of the bend portions 450B1 and 450B2 may have an angular shape and the other may have a rounded shape.

Referring to FIG. 8, the first portion TR1a of the first trench TR1 where the photodiode isolation pattern 450_4 is positioned may have a first length H1 along the third direction Z, the second portion TR1b may have a second length H2 along the third direction Z, and the third portion TR1c may have a third length H3 along the third direction Z.

Accordingly, the first portion 451P1 of the insulating isolation pattern 451 positioned within the first portion TR1a of the first trench TR1 may have a first length H1 along the third direction Z, the second portion 451P2 of the insulating isolation pattern 451 positioned within the second portion TR1b of the first trench TR1 may have a second length H2 along the third direction Z, and the third portion 451P3 of the insulating isolation pattern 451 positioned within the third portion TR1c of the first trench TR1 may have a third length H3 along the third direction Z.

In the embodiments shown in FIG. 8, the first length H1, the second length H2, and the third length H3 may be substantially the same. Here, “same” can mean not only something that is completely the same, but also something that includes fine differences that may occur due to process margins, etc. However, the relationship of the first length H1, the second length H2, and the third length H3 may be changed in various ways. For example, at least one of the first length H1, the second length H2, and the third length H3 may be different.

Specifically, as in the embodiments illustrated in FIG. 9, the first length H1 of the first portion 451P1 of the insulating isolation pattern 451 along the third direction Z, the second length H2 of the second portion 451P2 along the third direction Z, and the third length H3 of the third portion 451P3 along the third direction Z may be different.

For example, as shown in FIG. 9, the first length H1 may be greater than the second length H2 and the third length H3, and the second length H2 may be less than the first length H1 and greater than the third length H3. The third length H3 may be smaller than the first length H1 and the second length H2. That is, the first length H1 may be the largest, and the third length H3 may be the smallest.

As shown in FIG. 9, when the first length H1 is the largest and the third length H3 is the smallest, among the first to third portions 451P1, 451P2, and 451P3 of the insulating isolation pattern 451 included in the photodiode isolation pattern 450_5, the area or length of the first portion 451P1, which has the largest width along the first direction X, is the largest, thereby effectively preventing or reducing the crosstalk phenomenon between the adjacent pixels.

The shape of the photodiode isolation pattern 450_6 according to the embodiments illustrated in FIG. 10 is different from the shape of the photodiode isolation pattern 450_4 according to the embodiments illustrated in FIG. 8 as a difference.

Referring to FIG. 10, unlike the embodiments shown in FIG. 8, the photodiode isolation pattern 450_6 is different in that each of the first portion TR1a, the second portion TR1b, and the third portion TR1c of the first trench TR1 where it is positioned includes a sloped side surface with respect to the second surface 400b of the substrate 400.

Specifically, each of the first portion TR1a, the second portion TR1b, and the third portion TR1c of the first trench TR1 where the photodiode isolation pattern 450_6 is positioned may have a shape in which the width along the first direction X decreases from the first surface 400a of the substrate 400 to the second surface 400b.

The minimum width in the first direction X of the first portion TR1a of the first trench TR1 may be greater than the maximum width in the first direction X of the second portion TR1b of the first trench TR1, and the minimum width in the first direction X of the second portion TR1b of the first trench TR1 may be greater than the maximum width in the first direction X of the third portion TR1c of the first trench TR1.

Accordingly, the photodiode isolation pattern 450_6 positioned within the first trench TR1 may have the maximum width at the first surface 450_6S1 in contact with the first surface 400a of the substrate 400, and the minimum width at the second surface 450_6S2 in contact with the second surface 400b of the substrate 400.

Since each of the first portion TR1a, the second portion TR1b, and the third portion TRc of the first trench TR1, where the photodiode isolation pattern 450_6 is positioned, includes the sloped side surface, each of the first portion 451P1, the second portion 451P2, and the third portion 451P3 of the insulating isolation pattern 451 positioned within the first trench TR1 may include the sloped side surface with respect to the second surface 400b of the substrate 400. That is, each of the side surfaces of the first portion 451P1, the second portion 451P2, and the third portion 451P3 of the insulating isolation pattern 451 may have a reverse taper slope.

Specifically, the side surface of the first portion 451P1 of the insulating isolation pattern 451 may be positioned on the first bend portion 450B1 and form a third angle θ3 with a first imaginary line VL1 extending along the first direction X in parallel with the second surface 400b of the substrate 400.

The side surface of the second portion 451P2 of the insulating isolation pattern 451 may be positioned on the second bend portion 450B2 and form a fourth angle θ4 with the second imaginary line VL2 extending along the first direction X in parallel with the second surface 400b of the substrate 400.

The side surface of the third portion 451P3 of the insulating isolation pattern 451 may form a fifth angle θ5 with the second surface 400b of the substrate 400.

Here, the third angle θ3 may mean an angle measured from the first imaginary line VL1 along the counterclockwise direction to the side of the first portion 451P1 of the insulating isolation pattern 451, the fourth angle θ4 may an angle measured from the second imaginary line VL2 along the counterclockwise direction to the side of the second portion 451P2 of the insulating isolation pattern 451, and the fifth angle θ5 may mean an angle measured from the second surface 400b of the substrate 400 to the side surface of the third portion 451P3 of the insulating isolation pattern 451 along the counterclockwise direction.

In the present embodiments, the second angle θ2 formed by the second surface 400b of the substrate 400 and the side surface of the conductive isolation pattern 453 may be different from at least one of the third angle θ3, the fourth angle θ4, and the fifth angle θ5. For example, the second angle θ2 may be larger than the third angle θ3, the fourth angle θ4, and the fifth angle θ5. That is, the slope of the side of the conductive isolation pattern 453 may be steeper or greater than the slopes of the side of each of the first portion 451P1, the second portion 451P2, and the third portion 451P3 of the insulating isolation pattern 451. However, this is an example, and the relationships among the second angle θ2, the third angle θ3, the fourth angle θ4, and the fifth angle θ5 may be changed in various ways. For example, the second angle θ2 may be substantially the same as at least one of the third angle θ3, the fourth angle θ4, and the fifth angle θ5.

Here, “same” can mean not only something that is completely the same, but also something that includes fine differences that may occur due to process margins, etc.

In the present embodiments, at least one of the third angle θ3, the fourth angle θ4, and the fifth angle θ5 may be different. For example, the fifth angle θ5 may be smaller than the third angle θ3 and the fourth angle θ4, and the fourth angle θ4 may be smaller than the third angle θ3 and larger than the fifth angle θ5. That is, the fifth angle θ5 may be the smallest, and the third angle θ3 may be the largest.

Accordingly, the side slope of the first portion 451P1 of the insulating isolation pattern 451 may be the steepest or greatest, and the side slope of the third portion 451P3 of the insulating isolation pattern 451 may be the gentlest or smallest. However, this is an example, and at least one of the third angle θ3, the fourth angle θ4, and the fifth angle θ5 may be substantially the same. That is, at least one of the side slopes of the first portion 451P1, the second portion 451P2, and the third portion 451P3 of the insulating isolation pattern 451 may be substantially the same.

Here, “same” may mean not only something that is completely the same, but also something that includes fine differences that may occur due to process margins, etc.

The relationships of the first width W1 and the second width W2 of the insulating isolation pattern 451, the third width W3 of the conductive isolation pattern 453 and the buried insulating pattern 455, the fourth width W4 of the conductive isolation pattern 453, the fifth width W5 of the buried insulating pattern 455, and the sixth width W6 and the seventh width W7 of the photodiode isolation pattern 450_6 shown in FIG. 10, and the numerical ranges for the ratios thereof may be substantially equally applied with the contents described with reference to FIG. 4, so that detailed descriptions thereof are omitted.

According to the image sensor according to the embodiments illustrated in FIG. 8 to FIG. 10, substantially the same effect may be achieved as the image sensor according to the embodiments illustrated in FIG. 4.

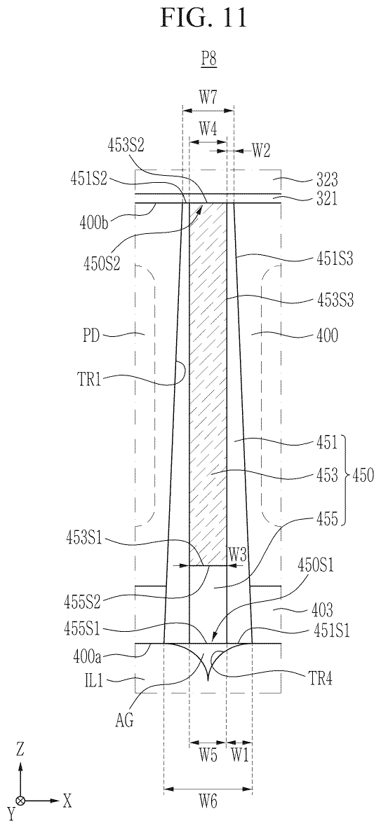

According to the image sensor according to the embodiments illustrated in FIG. 11, unlike the embodiments illustrated in FIG. 4, the photodiode isolation pattern 450 and the reflection member 460 positioned to overlap in the third direction Z are replaced with an air gap (AG) as a difference. That is, in the present embodiments, the air gap AG may be positioned in a region corresponding to the position of the reflection member 460 according to the embodiments illustrated in FIG. 4.

The photodiode isolation pattern 450 according to the image sensor according to the present embodiment is substantially the same as the photodiode isolation pattern 450 according to the embodiments illustrated in FIG. 4 so that the descriptions thereof are omitted and the air gap AG positioned to at least partially overlap the photodiode isolation pattern 450 in the third direction Z is focused.

Specifically, referring to FIG. 11, the air gap AG can be formed by at least partially filling the fourth trench TR4, which is formed by recessing a portion of the first insulating layer IL1, with air. The air gap AG may be positioned between the first insulating layer IL1 and the photodiode isolation pattern 450.

The air gap AG may be positioned to overlap at least a portion of the photodiode isolation pattern 450 in the third direction Z perpendicular to the first surface 400a of the substrate 400. The air gap AG may be positioned on the first surface 400a of the substrate 400.

In FIG. 11, the air gap AG is shown as completely overlapping the photodiode isolation pattern 450 in the third direction Z, but the overlap relationship between the air gap AG and the photodiode isolation pattern 450 is not limited to this and may be changed in various ways.

The air gap AG may be surrounded by the first insulating layer IL1 and the photodiode isolation pattern 450. That is, the air gap AG may be in contact with the inner wall of the fourth trench TR4 and the first surface 450S1 of the photodiode isolation pattern 450. In other words, the air gap AG may be in contact with the inner side wall of the fourth trench TR4 and the first surface 400a of the substrate 400. However, the present disclosure is not limited thereto, and unlike as illustrated in FIG. 11, another layer may be positioned between the first insulating layer IL1 and the photodiode isolation pattern 450 or the first surface 400a of the substrate 400, and the air gap AG may not be in direct contact with the photodiode isolation pattern 450.

The fourth trench TR4 where the air gap AG is positioned may have a shape such that the width of the fourth trench TR4 along the first direction X decreases as it moves away from the first surface 400a of the substrate 400. Additionally, the inner side wall of the fourth trench TR4 may include a curved surface. That is, the inner side wall of the fourth trench TR4 may have a shape that is concavely recessed toward the center.

Accordingly, the shape of the air gap AG positioned within the fourth trench TR4 may be defined by the shape of the fourth trench TR4.

However, the shape of the fourth trench TR4 is not limited to this and may be changed in various ways. For example, the width of the fourth trench TR4 in the first direction X may increase as it moves away from the first surface 400a of the substrate 400. As another example, the fourth trench TR4 may have a polygon shape on a cross-section. As another example, the inner side wall of the fourth trench TR4 may have a shape convex in the direction away from the center of fourth trench TR4.

In this way, as the shape of the fourth trench TR4 changes in various ways, the shape of the air gap AG positioned within the fourth trench TR4 may also change in various ways.

In the present embodiments, the maximum width of the fourth trench TR4 along the first direction X may be substantially the same as the width of the first surface 450S1 of the photodiode isolation pattern 450 along the first direction X. That is, the maximum width of the air gap AG along the first direction X may be substantially the same as the sixth width W6, which is the maximum width of the photodiode isolation pattern 450.

Here, “same” can mean not only something that is completely the same, but also something that includes fine differences that may occur due to process margins, etc. However, this is an example, and the maximum width of the fourth trench TR4 or the air gap AG along the first direction X may be smaller than the width of the first surface 450S1 of the photodiode isolation pattern 450 along the first direction X.

The image sensor according to the present embodiment may have substantially the same effect as the embodiments shown in FIG. 4.

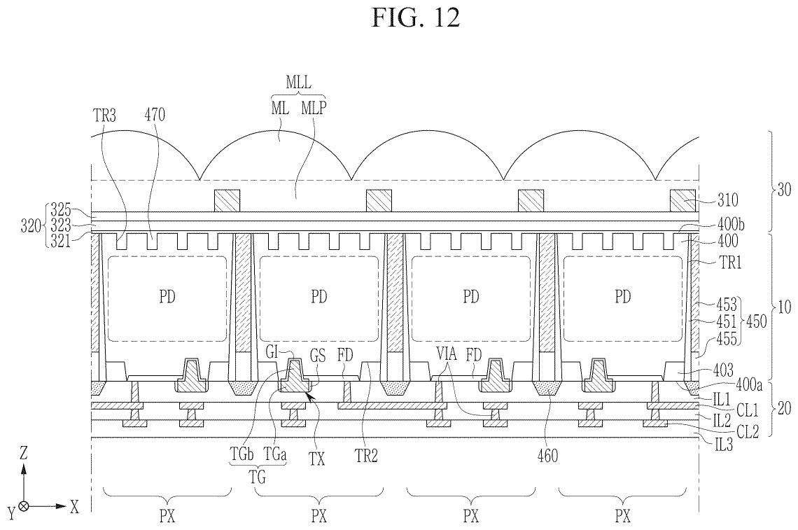

FIG. 12 is a cross-sectional view showing a cross-section of an image sensor according to some embodiments.

According to the embodiments illustrated in FIG. 12, unlike the embodiments illustrated in FIG. 3, there is a difference in that a photoconversion layer 10 and a light transmitting layer 30 are shifted and positioned. That is, according to the embodiments illustrated in FIG. 12, unlike the embodiments illustrated in FIG. 3, there is a difference in that the grid pattern 310 and the micro lens ML of the micro lens layer MLL are shifted from the center of the photodiodes PD.

In the present embodiments, the grid pattern 310 may be positioned so as to overlap a portion of the photodiode isolation pattern 450 in the third direction Z as the grid pattern 310 is shifted from the center of the photodiode PD. That is, the center of the grid pattern 310 and the center of the photodiode isolation pattern 450 can be positioned so as to be misaligned. However, the arrangement relationship of grid pattern 310 and photodiode isolation pattern 450 in the third direction Z is not limited to this and may be changed in various ways. For example, grid pattern 310 may be positioned shifted from the center of the photodiode PD so as to not overlap the photodiode isolation pattern 450 in the third direction Z.

The center of the micro lens ML may be shifted and positioned so as to be misaligned with the center of the photodiode PD. That is, the thickest part of the micro lens ML may be positioned so as to be misaligned with the center of the photodiode PD.

Additionally, the micro lens ML may be further shifted from the center of the photodiode PD compared to the degree to which the grid pattern 310 is shifted from the center of the photodiode PD.

Here, “overlap” may mean not only the overlap relationship along the third direction Z, which is the vertical direction, but also the overlap relationship along the moving direction of the light incident on the photodiode PD. That is, the photodiode PD and the micro lens ML may be positioned to overlap along the path direction of light incident on the photodiode PD from the outside. For example, since the center of the photodiode PD and the center of the micro lens ML are positioned so as to be staggered from each other, the center of the photodiode PD and the center of the micro lens ML may be positioned on an extension of the path of light incident on the photodiode PD.

In this way, the grid pattern 310 and the micro lens ML are shifted and positioned from the center of the photodiode PD according to the region of the substrate 400 is to compensate for the fact that the light entering the photodiode PD at an oblique angle becomes more intense as it moves away from the center of the substrate 400, so that the light entering at an oblique angle can be positioned at the center of the photodiode PD.

In the present embodiments, the degree to which the grid pattern 310 and the micro lens ML are shifted from the center of the photodiodes PD may increase as they move away from the center of the pixel array region of the substrate 400 (referring to ‘AR’ in FIG. 1), i.e., toward the periphery of the substrate (referring to ‘400’ in FIG. 1).

Accordingly, the arrangement relationship between the grid pattern 310, the micro lens ML, and the photodiode PD positioned adjacent to the pixel array region AR may be different from the arrangement relationship between the grid pattern 310, the micro lens ML, and the photodiode PD positioned far from the pixel array region AR. For example, FIG. 3 may show the arrangement relationship between the grid pattern 310, the micro lens ML, and the photodiode PD positioned at the center of the substrate 400. FIG. 12 may show the arrangement relationship between the grid pattern 310, the micro lens ML, and the photodiode PD, which are positioned spaced apart from the center of the substrate 400.

Additionally, the width of the grid pattern 310 and/or the micro lens ML may vary depending on the region of the substrate 400. For example, the width of the grid pattern 310 and the width of the micro lens ML positioned adjacent to the center of the substrate 400 may be different from the width of the grid pattern 310 and the width of the micro lens ML positioned far from the center of the substrate 400, respectively.

This is to compensate for the fact that, as described above, light incident on the photodiode PD in regions other than the center of the substrate 400 enters at an oblique angle, so that light incident at an oblique angle may be positioned at the center of the photodiode PD.

According to the embodiments image sensor illustrated in FIG. 12, it may have substantially the same effect as the image sensor according to the embodiments illustrated in FIG. 3.

While this disclosure has been described in connection with the present embodiments, it is to be understood that the disclosure is not limited to the disclosed embodiments, but is intended to cover various modifications and equivalent arrangements included within the spirit and scope of the appended claims.

What is claimed is:

1. An image sensor comprising:
a substrate comprising a first surface and a second surface facing the first surface,
a plurality of photodiodes in the substrate,
an element isolation pattern adjacent to the first surface of the substrate, and
a photodiode isolation pattern that extends into the element isolation pattern and is between the plurality of photodiodes,
wherein the photodiode isolation pattern comprises:
a conductive isolation pattern that extends into at least a portion of the substrate, and
an insulating isolation pattern that extends around the conductive isolation pattern,
wherein a width in a first direction of a first surface of the insulating isolation pattern adjacent to the first surface of the substrate is greater than a width in the first direction of a second surface of the insulating isolation pattern adjacent to the second surface of the substrate, and
wherein a slope relative to the second surface of the substrate of a side of the conductive isolation pattern is greater than a slope relative to the second surface of the substrate of a side of the insulating isolation pattern.

2. The image sensor of claim 1, wherein:
a width in the first direction of a first surface of the photodiode isolation pattern adjacent to the first surface of the substrate is greater than a width in the first direction of a second surface of the photodiode isolation pattern adjacent to the second surface of the substrate.

3. The image sensor of claim 2, wherein:
a side of the photodiode isolation pattern has a reverse taper slope.

4. The image sensor of claim 3, wherein:
the side of the photodiode isolation pattern comprises a bend portion having a stepped shape.

5. The image sensor of claim 2, wherein:
a ratio of the width in the first direction of the first surface of the insulating isolation pattern and the width in the first direction of the second surface of the insulating isolation pattern is about 1.5:1 to 3:1.

6. The image sensor of claim 5, wherein:
a ratio of a width in the first direction of a first end of the conductive isolation pattern adjacent to the first surface of the substrate and a width in the first direction of a second end of the conductive isolation pattern adjacent to the second surface of the substrate is less than or equal to about 1.05:1.

7. The image sensor of claim 2, wherein:
a maximum width in the first direction of the insulating isolation pattern is less than a maximum width in the first direction of the conductive isolation pattern, and
a minimum width in the first direction of the insulating isolation pattern is less than a minimum width in the first direction of the conductive isolation pattern.

8. The image sensor of claim 2, wherein:
the photodiode isolation pattern further comprises a buried insulating pattern on the conductive isolation pattern, and
the insulating isolation pattern extends around the buried insulating pattern.

9. The image sensor of claim 8, wherein:
a ratio of the width in the first direction of the first surface of the photodiode isolation pattern and the width in the first direction of the second surface of the photodiode isolation pattern is about 1.2:1 to 2:1.

10. The image sensor of claim 8, further comprising:
a reflection member that is on the first surface of the substrate and at least partially overlaps the photodiode isolation pattern in a second direction that is perpendicular to the first direction.

11. The image sensor of claim 10, wherein:
the reflection member comprises an air gap.

12. The image sensor of claim 2, wherein the insulating isolation pattern further comprises:
a first insulating isolation pattern that extends around the conductive isolation pattern, and
a second insulating isolation pattern between the conductive isolation pattern and the first insulating isolation pattern,
wherein a width in the first direction of the first insulating isolation pattern is less than a width in the first direction of the second insulating isolation pattern.

13. The image sensor of claim 1, further comprising:
a scattering pattern adjacent to the second surface of the substrate, and
a micro lens layer that comprises a flat portion and a micro lens and is on the second surface of the substrate.

14. The image sensor of claim 13, further comprising:
a plurality of grid patterns on the second surface of the substrate,
wherein the flat portion is between and on ones of the plurality of grid patterns, and
wherein the micro lens is on the flat portion.

15. An image sensor comprising:
a substrate comprising a first surface and a second surface facing the first surface,
a plurality of photodiodes in the substrate,
an element isolation pattern adjacent to the first surface of the substrate,
a photodiode isolation pattern that extends into the element isolation pattern and is between the plurality of photodiodes, and
a scattering pattern adjacent to the second surface of the substrate,
wherein the photodiode isolation pattern comprises an insulating isolation pattern that extends into at least a portion of the substrate and has a width in a first direction that decreases from the first surface of the substrate to the second surface of the substrate, and
wherein a ratio of a width of a first surface of the photodiode isolation pattern adjacent to the first surface of the substrate and a width of a second surface of the photodiode isolation pattern adjacent to the second surface of the substrate is about 1.2:1 to 2:1.

16. The image sensor of claim 15, wherein:
the photodiode isolation pattern further comprises:
a conductive isolation pattern, wherein the insulating isolation pattern extends around the conductive isolation pattern, and
a buried insulating pattern on the conductive isolation pattern, wherein the insulating isolation pattern extends around the buried insulating pattern, and
a ratio of a width of a first surface of the insulating isolation pattern adjacent to the first surface of the substrate and a width of a second surface of the insulating isolation pattern adjacent to the second surface of the substrate is about 1.5:1 to 3:1.

17. The image sensor of claim 16, wherein:
a ratio of a width in the first direction of a first end of the conductive isolation pattern adjacent to the first surface of the substrate and a width in the first direction of a second end of the conductive isolation pattern adjacent to the second surface of the substrate is less than or equal to about 1.05:1.

18. The image sensor of claim 16, further comprising:
an insulating layer on the first surface of the substrate,
wherein the insulating layer comprises an air gap that at least partially overlaps the photodiode isolation pattern in a second direction that is perpendicular to the first surface of the substrate.

19. The image sensor of claim 16, wherein:
a side of the photodiode isolation pattern comprises at least one bend portion having a stepped shape.

20. An image sensor comprising:
a substrate comprising a first surface and a second surface facing the first surface,
a plurality of photodiodes in the substrate,
an element isolation pattern adjacent to the first surface of the substrate,
a photodiode isolation pattern that extends into the element isolation pattern and is between the plurality of photodiodes,
a scattering pattern adjacent to the second surface of the substrate,
a plurality of grid patterns on the second surface of the substrate,
a micro lens layer comprising a flat portion that is between and on ones of the plurality of grid patterns and a micro lens on the flat portion, and
an air gap that is on the first surface of the substrate and at least partially overlaps the photodiode isolation pattern in a first direction that is perpendicular to the first surface of the substrate,
wherein the photodiode isolation pattern comprises:
a conductive isolation pattern that extends into at least a portion of the substrate,
a buried insulating pattern on the conductive isolation pattern, and
an insulating isolation pattern that extends around the conductive isolation pattern and the buried insulating pattern and has a width in a second direction that decreases from the first surface of the substrate to the second surface of the substrate, wherein the second direction is parallel to the first surface of the substrate,
wherein a ratio of a width of a first surface of the photodiode isolation pattern adjacent to the first surface of the substrate and a width of a second surface of the photodiode isolation pattern adjacent to the second surface of the substrate is about 1.2:1 to 2:1,
wherein a ratio of a width of a first surface of the insulating isolation pattern adjacent to the first surface of the substrate and a width of a second surface of the insulating isolation pattern adjacent to the second surface of the substrate is about 1.5:1 to 3:1, and
a slope relative to the second surface of the substrate of a side of the conductive isolation pattern is greater than a slope relative to the second surface of the substrate of the side of the insulating isolation pattern.
